(19) United States
(12) Patent Application Publication
(10) Pub. No.: US 2026/0354262 A1
(43) Pub. Date: Nov. 5, 2026

(54) SEMICONDUCTOR DEVICE

(71) Applicant: DENSO CORPORATION, Kariya-city (JP)

(72) Inventors: Kaisei SATO, Kariya-city (JP); Shoichiro OMAE, Kariya-city (JP); Yasuhiro OGAWA, Kariya-city (JP); Hiroki YOSHIKAWA, Kariya-city (JP)

(21) Appl. No.: 19/718,311

(22) Filed: Jun. 24, 2026

Related U.S. Application Data
(63) Continuation of application No. PCT/JP2024/045363, filed on Dec. 23, 2024.

(30) Foreign Application Priority Data
Dec. 27, 2023 (JP) 2023-222032

(51) Int. Cl. H10W 76/63

(52) U.S. Cl. CPC H10W 76/63

(57) ABSTRACT

A semiconductor device includes a semiconductor element, a substrate, and a sealing body. The substrate includes an insulating base material and a front-surface metal body disposed on a front surface of the insulating base material and electrically connected to a main electrode of the semiconductor element. The sealing body seals at least a portion of the substrate including the front-surface metal body, and the semiconductor element. The front-surface metal body has a contact portion in contact with the sealing body. The contact portion includes a high-adhesion portion having higher adhesion to the sealing body and a low-adhesion portion having lower adhesion to the sealing body than the high-adhesion portion. At least a portion of the high-adhesion portion is disposed between portions of the substrate having different potentials.

### CROSS REFERENCE TO RELATED APPLICATIONS

The present application is a continuation application of International Patent Application No. PCT/JP2024/045363 filed on Dec. 23, 2024, which designated the U.S. and claims the benefit of priority from Japanese Patent Application No. 2023-222032 filed on Dec. 27, 2023. The entire disclosures of all of the above applications are incorporated herein by reference.

### TECHNICAL FIELD

The disclosure in this specification relates to a semiconductor device.

### BACKGROUND

JP 2022-181818 A, which corresponds to US 2024/0079290A1, discloses a semiconductor device including a semiconductor element having a main electrode, a substrate in which metal bodies are disposed on both surfaces of an insulating base material, and a sealing body. The contents described in JP 2022-181818 A are incorporated herein by reference as an explanation of technical elements in this specification.

### SUMMARY

According to an aspect of the present disclosure, a semiconductor device may include: a semiconductor element having a main electrode; a substrate including an insulating base material, and a front-surface metal body disposed on a front surface of the insulating base material and electrically connected to the main electrode; and a sealing body sealing at least a portion of the substrate including the front-surface metal body, and the semiconductor element. The front-surface metal body may have a contact portion in contact with the sealing body. The contact portion may include a high-adhesion portion having higher adhesion to the sealing body and a low-adhesion portion having lower adhesion to the sealing body than the high-adhesion portion, and at least a portion of the high-adhesion portion may be disposed between portions of the substrate having different potentials.

### BRIEF DESCRIPTION OF DRAWINGS

FIG. 1 is a diagram showing a circuit configuration of a power conversion apparatus to which a semiconductor device according to a first embodiment is applied.

FIG. 2 is a perspective view of the semiconductor device.

FIG. 3 is a perspective view of the semiconductor device.

FIG. 4 is a plan view of the semiconductor device.

FIG. 5 is a cross-sectional view taken along a line V-V in FIG. 4.

FIG. 6 is a cross-sectional view taken along a line VI-VI in FIG. 4.

FIG. 7 is a cross-sectional view taken along a line VII-VII in FIG. 4.

FIG. 8 is a cross-sectional view taken along a line VIII-VIII in FIG. 4.

FIG. 9 is an enlarged view of a region IX shown in FIG. 8.

FIG. 10 is an exploded perspective view of the semiconductor device.

FIG. 11 is a plan view showing a state where semiconductor elements are mounted on a substrate on a drain electrode side.

FIG. 12 is a plan view of a circuit pattern of the substrate on the drain electrode side.

FIG. 13 is a plan view of a circuit pattern of a substrate on a source electrode side.

FIG. 14 is a diagram showing an arrangement of the circuit pattern on the drain electrode side, the semiconductor elements, and terminals.

FIG. 15 is a diagram showing an arrangement of the circuit pattern on the source electrode side, the semiconductor elements, and the terminals.

FIG. 16 is a plan view showing a current loop.

FIG. 17 is a plan view showing a distribution of high-adhesion portions on the substrate on a D side.

FIG. 18 is a plan view showing a distribution of high-adhesion portions on the substrate on an S side.

FIG. 19 is a diagram in which a pulling force is added to FIG. 9.

FIG. 20 is a cross-sectional view showing an uneven oxide film.

FIG. 21 is a plan view showing a distribution of high-adhesion portions on a substrate on a D side according to a second embodiment.

FIG. 22 is a plan view showing a distribution of high-adhesion portions on a substrate on a D side according to a third embodiment.

FIG. 23 is a plan view showing a distribution of high-adhesion portions on a substrate on an S side according to a fourth embodiment.

FIG. 24 is a plan view showing a distribution of high-adhesion portions on a substrate on an S side according to a fifth embodiment.

FIG. 25 is a cross-sectional view showing a semiconductor device according to the fifth embodiment.

### DETAILED DESCRIPTION

In a semiconductor device, if a sealing body peels off due to thermal stress, a leak path may occur between portions having different potentials of a substrate. As a result, reliability is likely to be degraded.

To address such an issue, if a measure is taken, such as roughening a surface of a front-surface metal body, to increase a degree of adhesion with the sealing body, peeling of the sealing body can be suppressed. However, the above measure requires effort, which leads to an increase in manufacturing costs.

The present disclosure provides a semiconductor device that achieves both a reduction in manufacturing costs and an improvement in reliability.

A semiconductor device according to an aspect of the present disclosure includes: a semiconductor element having a main electrode; a substrate including an insulating base material, and a front-surface metal body disposed on a front surface of the insulating base material and electrically connected to the main electrode; and a sealing body sealing at least a portion of the substrate including the front-surface metal body, and the semiconductor element. The front-surface metal body has a contact portion in contact with the sealing body. The contact portion includes a high-adhesion portion having higher adhesion to the sealing body, and a low-adhesion portion having lower adhesion to the sealing body than the high-adhesion portion. At least a portion of the high-adhesion portion is disposed between portions of the substrate having different potentials.

According to the semiconductor device disclosed above, in the contact portion of the front-surface metal body in contact with the sealing body, the low-adhesion portion is formed in addition to the high-adhesion portion. Therefore, compared to a case where an entire surface of the contact portion is the high-adhesion portion, an effort to form the high-adhesion portion can be reduced. Nevertheless, since the high-adhesion portion is disposed between the portions of the substrate having different potentials, peeling of the sealing body between the portions of the substrate having different potentials can be sufficiently suppressed. Thus, a concern that a leak path is formed between the portions having different potentials can be sufficiently suppressed.

As described above, according to the semiconductor device, it is possible to achieve both the reduction in the manufacturing costs and the improvement in reliability.

Hereinafter, multiple embodiments will be described with reference to the drawings. In each embodiment, corresponding components are denoted by the same reference numerals, and redundant description may be omitted. When only a part of a configuration is described in each embodiment, configurations of other embodiments described previously can be applied to other parts of the configuration. In addition, not only combinations of configurations explicitly shown in the description of each embodiment, but also configurations of multiple embodiments can be partially combined even if not explicitly shown, as long as there is no particular problem in the combination.

The semiconductor device of the present embodiment is applied to, for example, a power conversion apparatus of a moving object using a rotating electrical machine as a drive source. The moving object is, for example, an electrically driven vehicle such as an electric vehicle (EV), a hybrid vehicle (HV), or a plug-in hybrid vehicle (PHV), a flying object such as a drone, a ship, a construction machine, or an agricultural machine. An example applied to a vehicle will be described below.

### First Embodiment

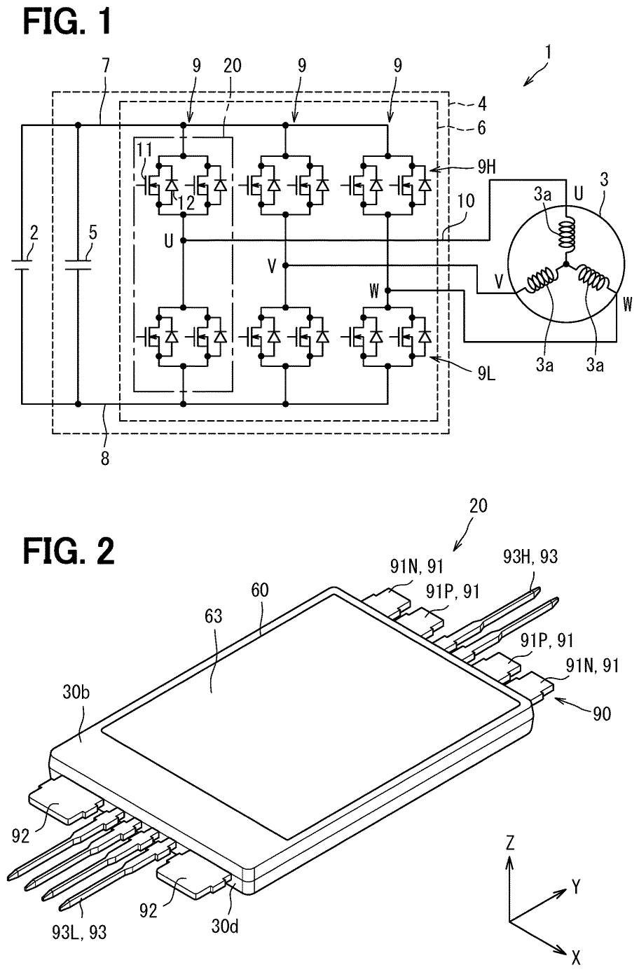

First, a schematic configuration of a vehicle drive system 1 will be described with reference to FIG. 1.

### <Vehicle Drive System>

As shown in FIG. 1, the vehicle drive system 1 includes a direct current (DC) power supply 2, a motor generator 3, and a power conversion apparatus 4.

The DC power supply 2 is a DC voltage source composed of a chargeable and dischargeable secondary battery. The secondary battery is, for example, a lithium-ion battery or a nickel-metal hydride battery. The motor generator 3 is a three-phase alternating current (AC) rotating electrical machine. The motor generator 3 functions as a travel drive source of the vehicle, that is, an electric motor. The motor generator 3 functions as a generator during regeneration. The power conversion apparatus 4 performs power conversion between the DC power supply 2 and the motor generator 3.

### <Power Conversion Apparatus>

Next, a circuit configuration of the power conversion apparatus 4 will be described with reference to FIG. 1. The power conversion apparatus 4 includes a power conversion circuit. The power conversion apparatus 4 of the present embodiment includes a smoothing capacitor 5 and an inverter 6 which is the power conversion circuit.

The smoothing capacitor 5 mainly smoothes a DC voltage supplied from the DC power supply 2. The smoothing capacitor 5 is connected to a P line 7 which is a high-potential side power supply line and an N line 8 which is a low-potential side power supply line. The P line 7 is connected to a positive electrode of the DC power supply 2, and the N line 8 is connected to a negative electrode of the DC power supply 2. A positive electrode of the smoothing capacitor 5 is connected to the P line 7 between the DC power supply 2 and the inverter 6. A negative electrode of the smoothing capacitor 5 is connected to the N line 8 between the DC power supply 2 and the inverter 6. The smoothing capacitor 5 is connected in parallel with the DC power supply 2.

The inverter 6 is a DC-AC conversion circuit. The inverter 6 converts the DC voltage into a three-phase AC voltage according to switching control by a control circuit (not shown), and outputs the three-phase AC voltage to the motor generator 3. Accordingly, the motor generator 3 is driven so as to generate a predetermined torque. During regenerative braking of the vehicle, the inverter 6 converts the three-phase AC voltage generated by the motor generator 3 upon receiving a rotational force from wheels into the DC voltage according to the switching control by the control circuit, and outputs the DC voltage to the P line 7. Thus, the inverter 6 performs bidirectional power conversion between the DC power supply 2 and the motor generator 3.

The inverter 6 includes upper and lower arm circuits 9 for three phases. The upper and lower arm circuit 9 is sometimes referred to as a leg. The upper and lower arm circuit 9 has an upper arm 9H and a lower arm 9L. The upper arm 9H and the lower arm 9L are connected in series between the P line 7 and the N line 8, with the upper arm 9H on a side of the P line 7. A connection point between the upper arm 9H and the lower arm 9L is connected to a winding 3a of a corresponding phase in the motor generator 3 via an output line 10. The inverter 6 has six arms. Each arm includes a switching element. At least a portion of each of the P line 7, the N line 8, and the output line 10 is composed of a conductive member such as a bus bar, for example.

In the present embodiment, an n-channel MOSFET 11 is employed as the switching element configuring each arm. The number of switching elements configuring each arm is not particularly limited. The number may be one or multiple. MOSFET is an abbreviation for Metal Oxide Semiconductor Field Effect Transistor.

As an example, each arm has two MOSFETs 11 in the present embodiment. The two MOSFETs 11 configuring one arm are connected in parallel. In the upper arm 9H, drains of the two MOSFETs 11 connected in parallel are connected to the P line 7. In the lower arm 9L, sources of the two MOSFETs 11 connected in parallel are connected to the N line 8. The sources of the two MOSFETs 11 connected in parallel in the upper arm 9H and the drains of the two MOSFETs 11 connected in parallel in the lower arm 9L are connected to each other. The two MOSFETs 11 connected in parallel are turned on and off at the same timing by a common gate drive signal (drive voltage).

A free-wheeling diode 12 is connected in anti-parallel to each of the MOSFETs 11. The diode 12 may be a parasitic diode (body diode) of the MOSFET 11 or may be provided separately from the parasitic diode. An anode of the diode 12 is connected to the source of the corresponding MOSFET 11, and a cathode thereof is connected to the drain. The upper and lower arm circuit 9 for one phase is provided by one semiconductor device 20. Details of the semiconductor device 20 will be described later.

The power conversion apparatus 4 may further include a converter as the power conversion circuit. The converter is a DC-DC conversion circuit that converts the DC voltage into a DC voltage of a different value. The converter is provided between the DC power supply 2 and the smoothing capacitor 5. The converter includes, for example, a reactor and the upper and lower arm circuit 9 described above. According to this configuration, voltage step-up and step-down are possible. The power conversion apparatus 4 may include a filter capacitor for removing power supply noise from the DC power supply 2. The filter capacitor is provided between the DC power supply 2 and the converter.

The power conversion apparatus 4 may include a drive circuit for the switching element configuring the inverter 6 and the like. The drive circuit supplies a drive voltage to a gate of the MOSFET 11 of the corresponding arm based on a drive command from the control circuit. The drive circuit drives, that is, turns on and off the corresponding MOSFET 11 by applying the drive voltage. The drive circuit is sometimes referred to as a driver.

The power conversion apparatus 4 may include a control circuit for the switching element. The control circuit generates a drive command for operating the MOSFET 11 and outputs the drive command to the drive circuit. The control circuit generates the drive command based on, for example, a torque request input from a host ECU (not shown) and signals detected by various sensors. ECU is an abbreviation for Electronic Control Unit.

The various sensors include, for example, a current sensor, a rotation angle sensor, and a voltage sensor. The current sensor detects a phase current flowing through the winding 3a of each phase. The rotation angle sensor detects a rotation angle of a rotor of the motor generator 3. The voltage sensor detects a voltage across the smoothing capacitor 5. The control circuit outputs, for example, a PWM signal as the drive command. The control circuit includes, for example, a processor and a memory. PWM is an abbreviation for Pulse Width Modulation.

### <Semiconductor Device>

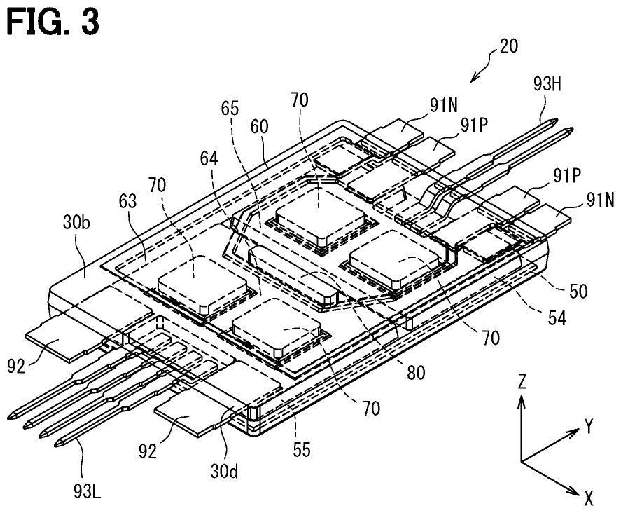

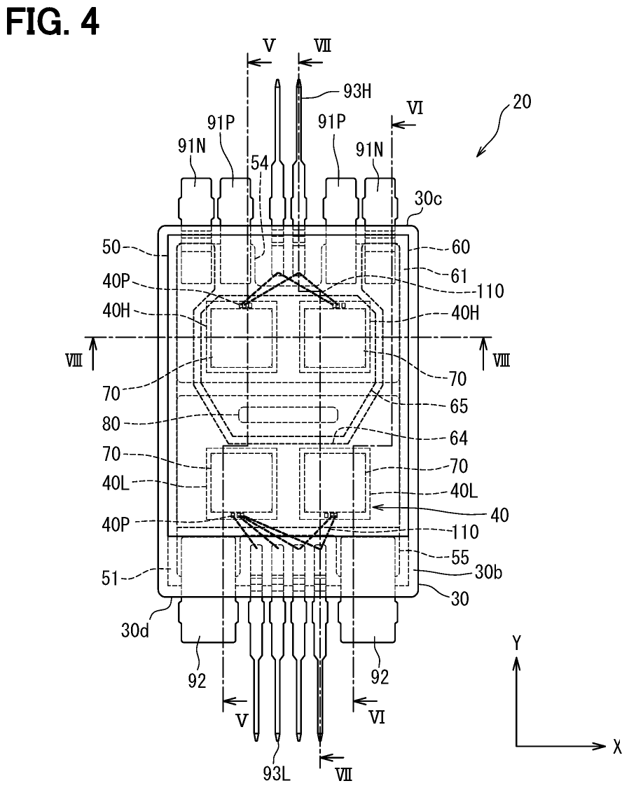

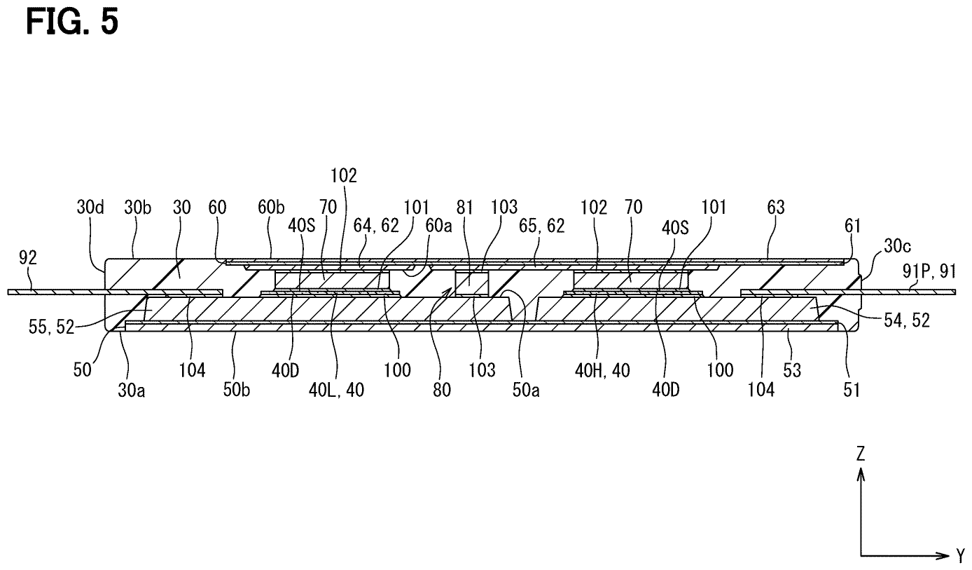

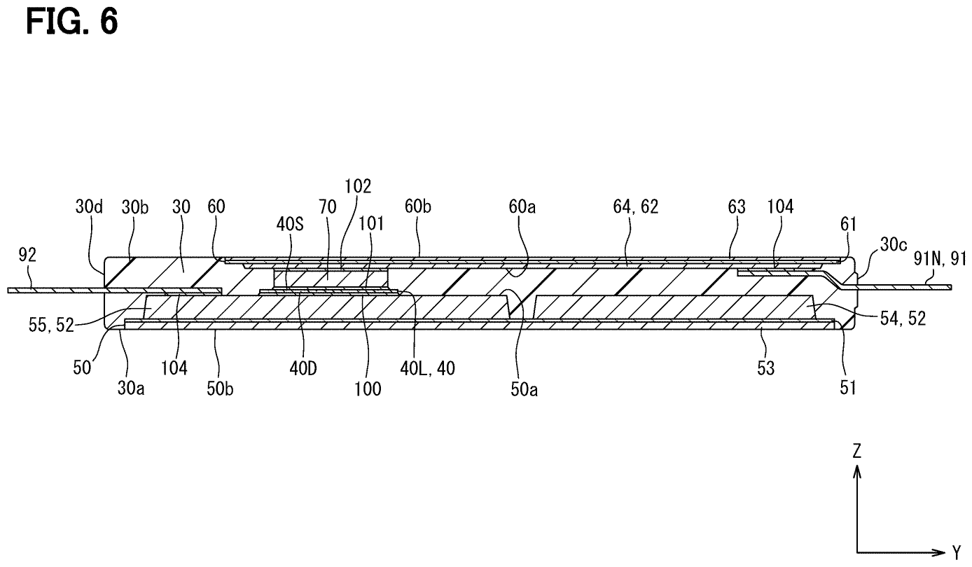

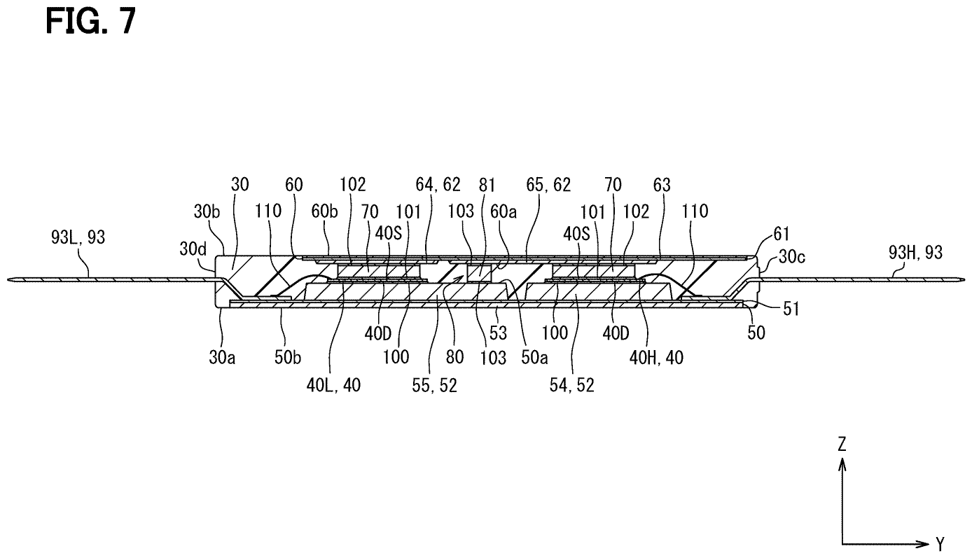

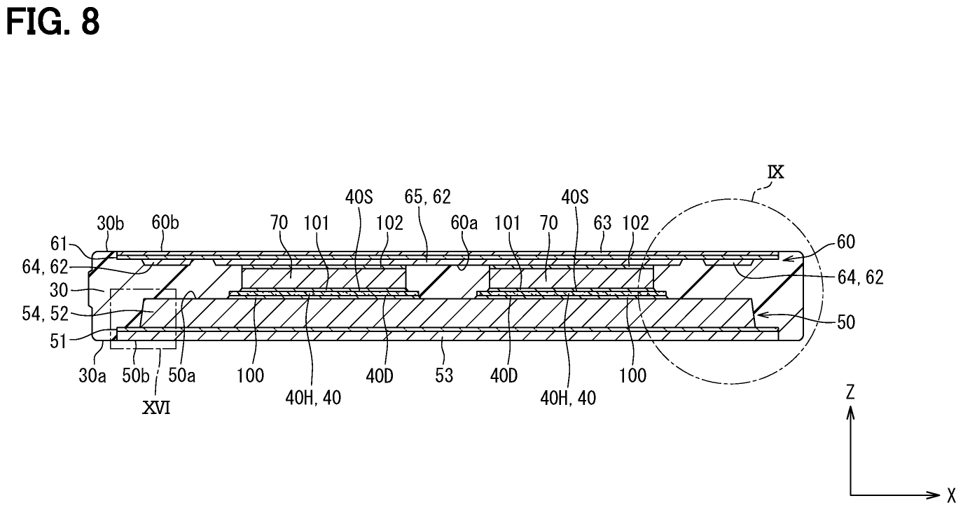

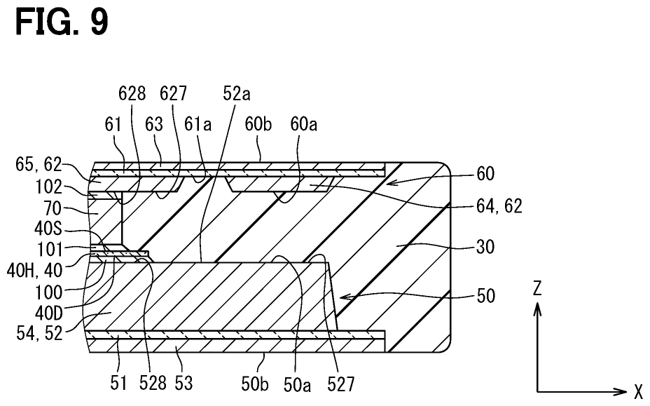

Next, the semiconductor device will be described with reference to FIGS. 2 to 13. FIG. 2 is a perspective view of the semiconductor device 20. FIG. 3 is a perspective view of the semiconductor device 20 similarly to FIG. 2. FIG. 3 is a transparent view showing an internal structure. FIG. 4 is a plan view of the semiconductor device 20. FIG. 4 is a transparent view showing an internal structure. FIG. 5 is a cross-sectional view taken along a line V-V in FIG. 4. FIG. 6 is a cross-sectional view taken along a line VI-VI in FIG. 4. FIG. 7 is a cross-sectional view taken along a line VII-VII in FIG. 4. FIG. 8 is a cross-sectional view taken along a line VIII-VIII in FIG. 4. FIG. 9 is an enlarged view of a region IX shown by an alternate long and short dash line in FIG. 8.

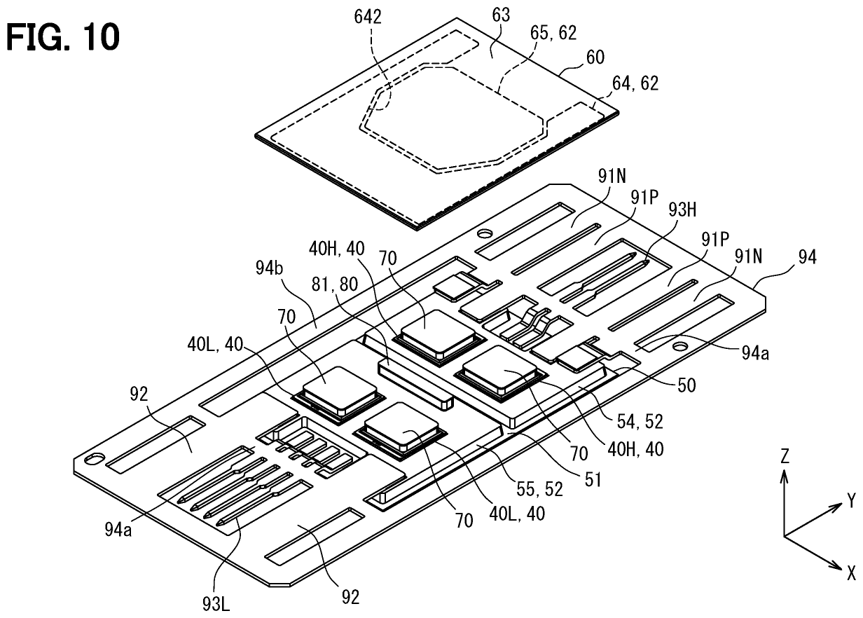

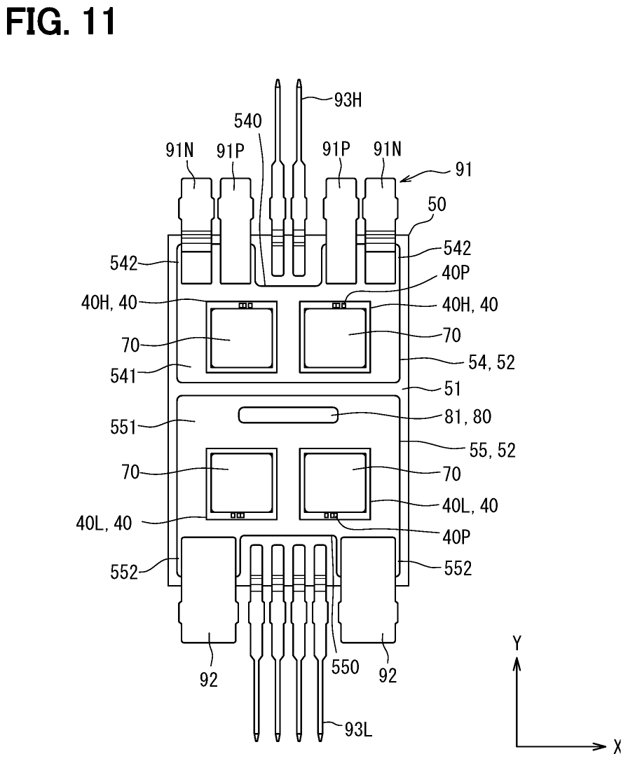

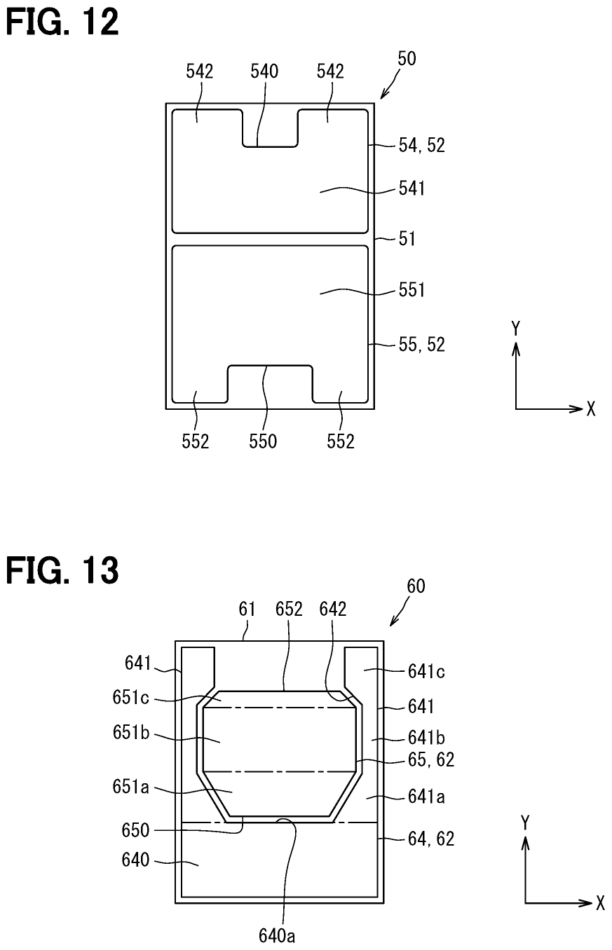

FIG. 10 is an exploded perspective view for explaining the semiconductor device 20. In FIG. 10, a lead frame 94 is shown for convenience. FIG. 11 is a plan view showing a state where a semiconductor element 40 is mounted on a substrate 50. FIG. 12 is a plan view showing a circuit pattern of a front-surface metal body 52 on the substrate 50. FIG. 13 is a plan view showing a circuit pattern of a front-surface metal body 62 on a substrate 60.

Hereinafter, a plate thickness direction of the semiconductor element (semiconductor substrate) is defined as a Z direction. A direction orthogonal to the Z direction, which is an arrangement direction of a semiconductor element configuring the upper arm 9H and a semiconductor element configuring the lower arm 9L, is defined as a Y direction. A direction orthogonal to both the Z direction and the Y direction is defined as an X direction. Unless otherwise specified, a shape in a plan view from the Z direction, in other words, a shape along an XY plane defined by the X direction and the Y direction, is defined as a planar shape. The plan view from the Z direction may be simply referred to as a plan view. Furthermore, arrangement is not limited to a mounting surface, and may be referred to as arrangement when there is an overlapping positional relationship in a plan view.

As shown in FIGS. 2 to 13, the semiconductor device 20 configures one of the upper and lower arm circuits 9 described above, that is, the upper and lower arm circuit 9 for one phase. The semiconductor device 20 includes a sealing body 30, the semiconductor elements 40, the substrates 50 and 60, conductive spacers 70, an arm connection portion 80, and external connection terminals 90.

The sealing body 30 seals a portion of other elements configuring the semiconductor device 20. Remaining portions of the other elements are exposed to the outside of the sealing body 30. The sealing body 30 is made of, for example, a resin. An example of the resin is an epoxy resin. The sealing body 30 is molded using a resin as a material by, for example, a transfer molding method. Such a sealing body 30 is sometimes referred to as a sealing resin body, a mold resin, or a resin molded body. The sealing body 30 may be formed using, for example, a gel. The gel is filled (disposed) in, for example, a facing region of the pair of substrates 50 and 60.

As shown in FIGS. 2 to 4, the sealing body 30 has a substantially rectangular planar shape. The sealing body 30 has, as surfaces forming an outer shell, a front surface 30a and a rear surface 30b that is a surface opposite to the front surface 30a in the Z direction. The front surface 30a and the rear surface 30b are, for example, flat surfaces. In addition, side surfaces that are surfaces connecting the front surface 30a and the rear surface 30b are provided. The side surfaces include two side surfaces 30c and 30d from which the external connection terminals 90 protrude. The side surface 30d is a surface opposite to the side surface 30c in the X direction.

The semiconductor element 40 is formed by forming a switching element on a semiconductor substrate made of a material such as silicon (Si) or a wide bandgap semiconductor having a wider bandgap than silicon. Examples of the wide bandgap semiconductor include silicon carbide (SiC), gallium nitride (GaN), gallium oxide (Ga₂O₃), and diamond. The semiconductor element 40 is sometimes referred to as a power element or a semiconductor chip.

The semiconductor element 40 of the present embodiment is formed by forming the n-channel MOSFET 11 described above on a semiconductor substrate made of SiC. The MOSFET 11 has a vertical structure such that a main current flows in a plate thickness direction of the semiconductor element 40 (semiconductor substrate), that is, in the Z direction. The semiconductor element 40 has main electrodes of the switching element on both surfaces in its own plate thickness direction, that is, in the Z direction. Specifically, as the main electrodes, the semiconductor element 40 has a drain electrode 40D on one surface, and has a source electrode 40S on a rear surface, which is a surface opposite to the one surface in the Z direction.

When the diode 12 is a parasitic diode, the source electrode 40S also serves as an anode electrode, and the drain electrode 40D also serves as a cathode electrode. The diode 12 may be configured in a chip separate from the MOSFET 11. The drain electrode 40D is a main electrode on a high potential side (first main electrode), and the source electrode 40S is a main electrode on a low potential side (second main electrode). Hereinafter, the drain electrode 40D and the source electrode 40S may be referred to as main electrodes 40D and 40S.

The semiconductor element 40 has a substantially rectangular planar shape. As shown in FIG. 11, the semiconductor element 40 has a pad 40P formed at a position different from the source electrode 40S on the rear surface. The source electrode 40S and the pad 40P are exposed from a protective film (not shown) formed on the rear surface of the semiconductor substrate. The drain electrode 40D is formed over almost the entire one surface. The source electrode 40S is formed on a portion of the rear surface of the semiconductor element 40. In a plan view, an area of the drain electrode 40D is larger than that of the source electrode 40S.

The pad 40P is an electrode for signals. The pad 40P is electrically isolated from the source electrode 40S. The pad 40P is formed at an end portion on a side opposite to a formation region of the source electrode 40S in the Y direction. The pad 40P includes a pad for a gate electrode.

The semiconductor device 20 includes a plurality of the semiconductor elements 40 having the above configuration. A configuration of each of the plurality of semiconductor elements 40 is common to each other. The plurality of semiconductor elements 40 includes semiconductor elements 40H configuring the upper arm 9H and semiconductor elements 40L configuring the lower arm 9L. The semiconductor element 40H is sometimes referred to as an upper arm element, and the semiconductor element 40L is sometimes referred to as a lower arm element. Each of the semiconductor elements 40H and 40L is an arm element configuring one arm. The semiconductor device 20 of the present embodiment has two semiconductor elements 40H and two semiconductor elements 40L. The two semiconductor elements 40H are arranged in the X direction. Similarly, the two semiconductor elements 40L are arranged in the X direction. The semiconductor elements 40H and the semiconductor elements 40L are arranged in the Y direction. The Y direction is a first direction orthogonal to the Z direction which is the plate thickness direction of the semiconductor element 40. The X direction is a second direction orthogonal to the Z direction and the first direction (Y direction). The semiconductor device 20 has two rows of the semiconductor elements 40H and the semiconductor elements 40L along the Y direction.

The respective semiconductor elements 40 are arranged at substantially the same position in the Z direction. The drain electrode 40D of each semiconductor element 40 faces the substrate 50. The source electrode 40S of each semiconductor element 40 faces the substrate 60. Hereinafter, the substrate 50 may be referred to as a substrate 50 on a D side, and the substrate 60 may be referred to as a substrate 60 on an S side.

The substrates 50 and 60 are arranged to sandwich the plurality of semiconductor elements 40 in the Z direction. The substrates 50 and 60 are arranged such that at least portions thereof face each other in the Z direction. The substrates 50 and 60 enclose all of the plurality of semiconductor elements 40 (40H, 40L) in a plan view.

The substrate 50 is disposed on a side of the drain electrode 40D with respect to the semiconductor element 40. The substrate 60 is disposed on a side of the source electrode 40S with respect to the semiconductor element 40. The substrate 50 is electrically connected to the drain electrode 40D as will be described later, and provides a wiring function. Similarly, the substrate 60 is electrically connected to the source electrode 40S and provides a wiring function. Therefore, the substrates 50 and 60 are sometimes referred to as wiring substrates. The substrate 50 may be referred to as a drain substrate or a D-side substrate, and the substrate 60 may be referred to as a source substrate or an S-side substrate. The substrates 50 and 60 provide a heat dissipation function of dissipating heat generated by the semiconductor elements 40. Therefore, the substrates 50 and 60 are sometimes referred to as heat dissipation members. Of the pair of substrates 50 and 60 sandwiching the semiconductor elements 40 in the Z direction, the substrate 50 on the D side is sometimes referred to as a first substrate, and the substrate 60 on the S side is sometimes referred to as a second substrate.

The substrate 50 has a facing surface 50a facing the semiconductor elements 40, and a rear surface 50b that is a surface opposite to the facing surface 50a. The substrate 50 includes an insulating base material 51, the front-surface metal body 52, and a rear-surface metal body 53. The substrate 50 is a substrate in which the insulating base material 51 and the metal bodies 52 and 53 are stacked. The substrate 60 has a facing surface 60a facing the semiconductor elements 40, and a rear surface 60b that is a surface opposite to the facing surface 60a. The substrate 60 includes an insulating base material 61, the front-surface metal body 62, and a rear-surface metal body 63. The substrate 60 is a substrate in which the insulating base material 61 and the metal bodies 62 and 63 are stacked. In the substrate 50 which is the first substrate, the insulating base material 51 is a first insulating base material, the front-surface metal body 52 is a first front-surface metal body, and the rear-surface metal body 53 is a first rear-surface metal body. In the substrate 60 which is the second substrate, the insulating base material 61 is a second insulating base material, the front-surface metal body 62 is a second front-surface metal body, and the rear-surface metal body 63 is a second rear-surface metal body. Hereinafter, the front-surface metal bodies 52 and 62 and the rear-surface metal bodies 53 and 63 may be simply referred to as metal bodies 52, 53, 62, and 63.

The insulating base material 51 electrically isolates the front-surface metal body 52 from the rear-surface metal body 53. Similarly, the insulating base material 61 electrically isolates the front-surface metal body 62 from the rear-surface metal body 63. The insulating base materials 51 and 61 are sometimes referred to as insulating layers. A material of the insulating base materials 51 and 61 is a resin or an inorganic ceramic. As the resin, for example, an epoxy-based resin or a polyimide-based resin can be used. As the ceramic, for example, Al₂O₃ (alumina), Si₃N₄ (silicon nitride), or the like can be used. When the insulating base materials 51 and 61 are resins, the substrates 50 and 60 are sometimes referred to as metal resin substrates. When the insulating base materials 51 and 61 are ceramics, the substrates 50 and 60 are sometimes referred to as metal ceramic substrates.

In a case where the insulating base materials 51 and 61 use a resin material, an inorganic filler (inorganic filling material) may be included in the resin in order to improve heat dissipation, insulation, and the like. A linear expansion coefficient may be adjusted by adding the filler. As the filler, for example, Al₂O₃, SiO₂ (silicon dioxide), AlN (aluminum nitride), BN (boron nitride), or the like can be used. The insulating base materials 51 and 61 may include only one type of filler or may include a plurality of types of fillers.

Considering heat dissipation and insulation, in the case of a resin-based material, a thickness of each of the insulating base materials 51 and 61, that is, a length in the Z direction is preferably approximately 50 μm to 300 μm. In the case of a ceramic-based material, the thickness of each of the insulating base materials 51 and 61 is preferably approximately 200 μm to 500 μm. In the Z direction, a front surface of the insulating base materials 51 and 61 is an inner surface, that is, a surface adjacent to the semiconductor elements 40, and a rear surface, which is a surface opposite to the front surface in the Z direction, is an outer surface. The insulating base materials 51 and 61 may have a common (identical) material configuration or may be different from each other. In the present embodiment, the resin-based insulating base materials 51 and 61 are employed, and the material configurations are common. The linear expansion coefficient of the insulating base materials 51 and 61 is adjusted to substantially the same value as the sealing body 30 by adding the filler to the resin. By adding the filler to the resin, the linear expansion coefficient of the insulating base materials 51 and 61 and the sealing body 30 has a value close to that of a metal such as copper (Cu) configuring the metal bodies 52, 53, 62, and 63.

The metal bodies 52, 53, 62, and 63 are provided as, for example, a metal plate or a metal foil. The metal bodies 52, 53, 62, and 63 are formed using a metal having good conductivity and thermal conductivity, such as Cu and aluminum (Al), as a material. The thickness of each of the metal bodies 52, 53, 62, and 63 is, for example, approximately 0.1 mm to 3 mm. The front-surface metal body 52 is disposed on a front surface of the insulating base material 51 in the Z direction. The rear-surface metal body 53 is disposed on a rear surface of the insulating base material 51. Similarly, the front-surface metal body 62 is disposed on a front surface of the insulating base material 61 in the Z direction. The rear-surface metal body 63 is disposed on a rear surface of the insulating base material 61. The insulating base materials 51 and 61 face the semiconductor elements 40 in the Z direction. As shown in FIGS. 5 to 9 and the like, in the present embodiment, the front-surface metal body 52 is thicker than the rear-surface metal body 53. The front-surface metal body 62 is thicker than the rear-surface metal body 63. The front-surface metal body 52 on the side of the drain electrode 40D is thicker than the front-surface metal body 62 on the side of the source electrode 40S. Instead of this configuration, the rear-surface metal bodies 53 and 63 may be thicker than the corresponding front-surface metal bodies 52 and 62. The thicknesses of the front-surface metal body 52 and the rear-surface metal body 53 may be substantially equal to each other, or the thicknesses of the front-surface metal body 62 and the rear-surface metal body 63 may be substantially equal to each other.

The front-surface metal bodies 52 and 62 are patterned. The front-surface metal bodies 52 and 62 provide wiring, that is, circuits. Therefore, the front-surface metal bodies 52 and 62 are sometimes referred to as circuit patterns, wiring layers, or circuit conductors. The front-surface metal bodies 52 and 62 may include a plating film of a nickel (Ni)-based material, gold (Au), or the like on a metal surface. Hereinafter, the pattern of the front-surface metal bodies 52 and 62 may be referred to as a circuit pattern. The front-surface metal body 52 and a non-arrangement region of the front-surface metal body 52 on the front surface of the insulating base material 51 form the facing surface 50a of the substrate 50. Similarly, the front-surface metal body 62 and a non-arrangement region of the front-surface metal body 62 on the front surface of the insulating base material 61 form the facing surface 60a of the substrate 60.

For example, the front-surface metal bodies 52 and 62 patterned into a predetermined shape by press working, etching, or the like may be prepared and brought into close contact with a stacked body having a two-layer structure of the insulating base materials 51 and 61 and the rear-surface metal bodies 53 and 63 to form the substrates 50 and 60. After forming a stacked body having a three-layer structure of the front-surface metal bodies 52 and 62, the insulating base materials 51 and 61, and the rear-surface metal bodies 53 and 63, the front-surface metal bodies 52 and 62 may be patterned by cutting or etching.

As shown in FIG. 11 and the like, the front-surface metal body 52 has a P wiring 54 and a relay wiring 55. The P wiring 54 and the relay wiring 55 are electrically isolated by a predetermined interval (gap). The gap is filled with the sealing body 30.

The P wiring 54 is connected to a P terminal 91P, which will be described later, and the drain electrode 40D of the semiconductor element 40H. The P wiring 54 electrically connects the P terminal 91P and the drain electrode 40D of the semiconductor element 40H. The P wiring 54 is sometimes referred to as a positive electrode wiring or a high-potential power supply wiring. The relay wiring 55 is connected to the drain electrode 40D of the semiconductor element 40L, the arm connection portion 80, and an output terminal 92. The relay wiring 55 electrically connects the arm connection portion 80 and the drain electrode 40D of the semiconductor element 40L. The relay wiring 55 electrically connects the source electrode 40S of the semiconductor element 40H and the drain electrode of the semiconductor element 40L to the output terminal 92. In the front-surface metal body 52 (first front-surface metal body), the P wiring 54 is a first power supply wiring, and the relay wiring 55 is a first relay wiring.

The P wiring 54 and the relay wiring 55 are arranged side by side in the Y direction. In the Y direction, the P wiring 54 is arranged adjacent to the power supply terminal 91, and the relay wiring 55 is arranged adjacent to the output terminal 92. In other words, the P wiring 54 is arranged at a position close to the side surface 30c of the sealing body 30, and the relay wiring 55 is arranged at a position close to the side surface 30d.

The P wiring 54 has a notch 540. The notch 540 is open at one of four sides of a substantially rectangular planar shape having the X direction as a longitudinal direction. The notch 540 is provided at a substantially center in the X direction on a side facing the side surface 30c. The P wiring 54 includes a base portion 541 and a pair of extending portions 542. The base portion 541 and the pair of extending portions 542 define the notch 540. The P wiring 54 has a substantially U-shape (concave shape) in a plan view.

The base portion 541 is a portion closer to the relay wiring 55 than the notch 540 and the extending portions 542, and has a substantially rectangular planar shape. The base portion 541 overlaps the semiconductor element 40H in a plan view. That is, the semiconductor element 40H is arranged on the base portion 541. The drain electrode 40D of the semiconductor element 40H is connected to the base portion 541.

The two extending portions 542 extend from the base portion 541 in the same direction as each other, specifically, in the Y direction and toward the side surface 30c of the sealing body 30. Of the two extending portions 542, a first extending portion continues to the vicinity of a first end in the X direction of the base portion 541, and a second extending portion continues to the vicinity of a second end of the base portion 541. Both ends of the U-shape of the P wiring 54, that is, ends of the two extending portions 542 opposite to the base portion 541, are at substantially the same position in the Y direction. The pair of extending portions 542 sandwich the notch 540 in the X direction. A length in the Y direction of the base portion 541 is longer than a depth in the Y direction of the notch 540 and lengths in the Y direction of the extending portions 542.

The relay wiring 55 also has a notch 550. The notch 550 is open at one of four sides of a substantially rectangular planar shape. The notch 550 is provided at a substantially center in the X direction on a side facing the side surface 30d. That is, in the front-surface metal body 52, the notch 540 is provided at one of ends in the Y direction, and the notch 550 is provided at the other end.

The relay wiring 55 includes a base portion 551 and a pair of extending portions 552. The base portion 551 and the pair of extending portions 552 define the notch 550. The relay wiring 55 has a substantially U-shape (concave shape) in a plan view. The base portion 551 is a portion closer to the P wiring 54 side than the notch 550 and the extending portions 552, and has a substantially rectangular planar shape. The base portion 551 overlaps the semiconductor element 40L in a plan view. That is, the semiconductor element 40L is arranged on the base portion 551. The drain electrode 40D of the semiconductor element 40L is connected to the base portion 551.

The two extending portions 552 extend from the base portion 551 in the same direction as each other, specifically, in the Y direction and toward the side surface 30d of the sealing body 30. A first extending portion of the extending portions 552 continues to the vicinity of a first end in the X direction of the base portion 551, and a second extending portion continues to the vicinity of a second end of the base portion 551. Both ends of the U-shape of the relay wiring 55, that is, ends of the two extending portions 552 opposite to the base portion 551, are at substantially the same position in the Y direction. The pair of extending portions 552 sandwich the notch 550 in the X direction. A length in the Y direction of the base portion 551 is longer than a depth in the Y direction of the notch 550 and lengths in the Y direction of the extending portions 552.

On the other hand, as shown in FIGS. 10 and 13 and the like, the front-surface metal body 62 has an N wiring 64 and a relay wiring 65. The N wiring 64 and the relay wiring 65 are electrically isolated by a predetermined interval (gap). The gap is filled with the sealing body 30.

The N wiring 64 is connected to an N terminal 91N, which will be described later, and the source electrode 40S of the semiconductor element 40L. The N wiring 64 electrically connects the N terminal 91N and the source electrode 40S of the semiconductor element 40L. The N wiring 64 is sometimes referred to as an N-wiring. The relay wiring 65 is connected to the source electrode 40S of the semiconductor element 40H and the arm connection portion 80. The relay wiring 65 electrically connects the source electrode 40S of the semiconductor element 40H and the arm connection portion 80. In the front-surface metal body 62 (second front-surface metal body), the N wiring 64 is a second power supply wiring, and the relay wiring 65 is a second relay wiring.

The N wiring 64 includes a base portion 640 and a pair of extending portions 641. The N wiring 64 has a substantially U-shape in a plan view. The base portion 640 is arranged side by side with the relay wiring 65 in the Y direction. The base portion 640 is arranged adjacent to the side surface 30d in the Y direction. The base portion 640 has a substantially rectangular planar shape with the X direction as a longitudinal direction. As shown in FIG. 15, the base portion 640 overlaps the semiconductor element 40L in a plan view. That is, the semiconductor element 40L is arranged on the base portion 640. The source electrode 40S of the semiconductor element 40L is connected to the base portion 640.

The two extending portions 641 extend from the base portion 640 in the same direction as each other, specifically, in the Y direction and toward the side surface 30c of the sealing body 30. Of the two extending portions 641, a first extending portion continues to the vicinity of a first end in the X direction of the base portion 640, and a second extending portion continues to the vicinity of a second end of the base portion 640. Both ends of the U-shape of the N wiring 64, that is, ends of the two extending portions 641 opposite to the base portion 640, are at substantially the same position in the Y direction.

The pair of extending portions 641 forms both ends of the front-surface metal body 62 in the X direction. The pair of extending portions 641 is arranged near ends of the substrate 60. In a plan view, a portion of each of the pair of extending portions 641 overlaps the P wiring 54. A length in the Y direction of the extending portions 641 is longer than a length in the Y direction of the base portion 640. The N wiring 64 also has a notch 642. The notch 642 is open at one of four sides of a substantially rectangular planar shape having the Y direction as a longitudinal direction. The notch 642 is provided at a substantially center in the X direction on a side facing the side surface 30c. The base portion 640 and the pair of extending portions 641 define the notch 642.

As described above, the relay wiring 65 is arranged side by side with the N wiring 64, specifically, the base portion 640 in the Y direction. In the Y direction, the relay wiring 65 is arranged at a position close to the side surface 30c of the sealing body 30, and the base portion 640 is arranged at a position close to the side surface 30d. The relay wiring 65 is arranged between the pair of extending portions 641 in the X direction. The relay wiring 65 is sandwiched by the pair of extending portions 641. The relay wiring 65 is arranged within the notch 642. The relay wiring 65 is arranged with a predetermined interval (gap) between the relay wiring 65 and the N wiring 64. In a plan view, a portion of the relay wiring 65 overlaps the P wiring 54, and another portion overlaps the relay wiring 55.

As shown in FIG. 15, the relay wiring 65 overlaps the semiconductor element 40H in a plan view. That is, the semiconductor element 40H is arranged on the relay wiring 65. The source electrode 40S of the semiconductor element 40H is connected to the relay wiring 65. A more detailed example of the circuit pattern of the front-surface metal body 62 will be described later.

The rear-surface metal bodies 53 and 63 are electrically isolated from a circuit including the semiconductor elements 40 by the insulating base materials 51 and 61. The rear-surface metal bodies 53 and 63 are sometimes referred to as metal base substrates. Heat generated by the semiconductor elements 40 is transmitted to the rear-surface metal bodies 53 and 63 via the front-surface metal bodies 52 and 62 and the insulating base materials 51 and 61. The rear-surface metal bodies 53 and 63 provide a heat dissipation function. The rear-surface metal bodies 53 and 63 of the present embodiment have a substantially rectangular planar shape, and an outer profile thereof substantially matches an outer profile of the front-surface metal bodies 52 and 62. The rear-surface metal bodies 53 and 63 are so-called solid conductors disposed over substantially the entire rear surfaces of the insulating base materials 51 and 61. As described above, since the linear expansion coefficients of the insulating base materials 51 and 61 are adjusted by adding a filler, warping can be suppressed even if patterns are changed between a front surface and a rear surface. Of course, the rear-surface metal bodies 53 and 63 may be patterned so as to match the front-surface metal bodies 52 and 62 in a plan view.

The rear-surface metal bodies 53 and 63 of the present embodiment are disposed over substantially the entire areas of the rear surfaces of the corresponding insulating base materials 51 and 61. In order to further enhance a heat dissipation effect, at least one of the rear-surface metal bodies 53 and 63 may be exposed from the sealing body 30. In the present embodiment, the rear-surface metal body 53 is exposed from the front surface 30a of the sealing body 30, and the rear-surface metal body 63 is exposed from the rear surface 30b. An exposed surface of the rear-surface metal body 53 is substantially flush with the front surface 30a. An exposed surface of the rear-surface metal body 63 is substantially flush with the rear surface 30b. The rear-surface metal bodies 53 and 63 form the rear surfaces 50b and 60b of the substrates 50 and 60.

The conductive spacer 70 provides a spacer function for securing a predetermined gap between the semiconductor element 40 and the substrate 60. For example, the conductive spacer 70 secures a height for electrically connecting a corresponding signal terminal 93 to the pad 40P of the semiconductor element 40. The conductive spacer 70 is located in the middle of electrical conduction and heat conduction paths between the source electrode 40S of the semiconductor element 40 and the substrate 60, and provides a wiring function and a heat dissipation function. The conductive spacer 70 contains a metal material having good conductivity and thermal conductivity, such as Cu. The conductive spacer 70 may include a plating film on a surface. The conductive spacer 70 is a substantially rectangular columnar body having substantially the same size as the source electrode 40S in a plan view.

The conductive spacer 70 is sometimes referred to as a terminal, a terminal block, or a metal block body. The semiconductor device 20 includes the same number of the conductive spacers 70 as the semiconductor elements 40. Specifically, four conductive spacers 70 are provided. The conductive spacers 70 are individually connected to the semiconductor elements 40.

The arm connection portion 80 electrically connects the relay wirings 55 and 65. That is, the arm connection portion 80 electrically connects the upper arm 9H and the lower arm 9L. The arm connection portion 80 is provided between the semiconductor element 40H and the semiconductor element 40L in the Y direction. The arm connection portion 80 is provided in an overlapping region of the relay wiring 55 and the relay wiring 65 in a plan view. The arm connection portion 80 of the present embodiment includes a joint portion 81 and a joining material 103 described later.

The joint portion 81 is a metal columnar body provided separately from the front-surface metal bodies 52 and 62. Such a joint portion 81 is sometimes referred to as a joint terminal. In the Z direction, the joining material 103 is interposed between a first end of the joint portion 81 and the relay wiring 55, and the joining material 103 is interposed between a second end of the joint portion 81 and the relay wiring 65.

Alternatively, the joint portion 81 may be integrally continuous with at least one of the front-surface metal bodies 52 and 62. That is, the joint portion 81 may be provided integrally with the front-surface metal bodies 52 and 62 as a part of the substrates 50 and 60. The arm connection portion 80 may have a configuration not including the joint portion 81. That is, the arm connection portion 80 may include only the joining material 103.

The external connection terminal 90 is a terminal for electrically connecting the semiconductor device 20 to an external device. The external connection terminal 90 is formed using a metal material having good conductivity such as copper. The external connection terminal 90 is, for example, a plate material. The external connection terminal 90 is sometimes referred to as a lead. The external connection terminal 90 includes a power supply terminal 91, the output terminal 92, and the signal terminal 93. The power supply terminal 91 includes the P terminal 91P and the N terminal 91N. The P terminal 91P, the N terminal 91N, and the output terminal 92 are main terminals electrically connected to the main electrodes of the semiconductor element 40. The signal terminal 93 includes a signal terminal 93H on a side of the upper arm 9H and a signal terminal 93L on a side of the lower arm 9L.

The power supply terminal 91 is the external connection terminal 90 electrically connected to the power supply lines 7 and 8 described above. The P terminal 91P is electrically connected to a positive electrode terminal of the smoothing capacitor 5. The P terminal 91P is sometimes referred to as a positive electrode terminal or a high-potential power supply terminal. The P terminal 91P is connected to the P wiring 54 of the front-surface metal body 52. That is, the P terminal 91P is connected to the drain electrode 40D of the semiconductor element 40H configuring the upper arm 9H.

The P terminal 91P is connected near one end of the P wiring 54 in the Y direction. The P terminal 91P extends in the Y direction from a connection portion (joint portion) with the P wiring 54, and protrudes outside the sealing body 30 from the vicinity of a center in the Z direction at the side surface 30c. The semiconductor device 20 of the present embodiment includes two P terminals 91P. As shown in FIG. 11, a first P terminal 91P is connected to a first extending portion of the pair of extending portions 542, and a second P terminal 91P is connected to a second extending portion of the pair of extending portions 542. The P terminals 91P are arranged at positions close to the notch 540 in the respective extending portions 542, that is, inwardly, so as to be adjacent to the N terminals 91N in a plan view. The two P terminals 91P are arranged side by side in the X direction. The two P terminals 91P are arranged at substantially the same position in the Z direction.

The N terminal 91N is electrically connected to a negative electrode terminal of the smoothing capacitor 5. The N terminal 91N is sometimes referred to as a negative electrode terminal or a low-potential power supply terminal. The N terminal 91N is connected to the N wiring 64 of the front-surface metal body 62. That is, the N terminal 91N is connected to the source electrode 40S of the semiconductor element 40L configuring the lower arm 9L.

The N terminal 91N is connected near one end of the N wiring 64 in the Y direction. The N terminal 91N extends in the Y direction from a joint portion with the N wiring 64, and protrudes outside the sealing body 30 from the vicinity of a center in the Z direction at the side surface 30c. The semiconductor device 20 includes two N terminals 91N. As shown in FIG. 15 and the like, a first N terminal 91N is connected to a first extending portion of the pair of extending portions 641, and a second N terminal 91N is connected to a second extending portion of the pair of extending portions 641. The two N terminals 91N are arranged side by side in the Y direction. The two N terminals 91N are arranged at substantially the same position in the Z direction.

The two N terminals 91N are arranged outside the two P terminals 91P in the X direction. In a plan view, a first N terminal 91N is arranged in the vicinity of a first P terminal 91P, and a second N terminal 91N is arranged in the vicinity of a second P terminal 91P. Side surfaces of the N terminal 91N and the P terminal 91P adjacent to each other in the X direction face each other at a portion including a portion protruding from the sealing body 30.

The output terminal 92 is electrically connected to the winding 3a (stator coil) of the corresponding phase in the motor generator 3. The output terminal 92 is sometimes referred to as an O terminal, an AC terminal, or the like. As shown in FIGS. 3 and 7, the output terminal 92 is connected to the relay wiring 55 of the front-surface metal body 52 on the substrate 50. That is, the output terminal 92 is connected to the connection point between the upper arm 9H and the lower arm 9L.

The output terminal 92 is connected near one end of the relay wiring 55 in the Y direction. The output terminal 92 extends in the Y direction from a joint portion with the relay wiring 55, and protrudes outside the sealing body 30 from the vicinity of a center in the Z direction at the side surface 30d. The semiconductor device 20 includes two output terminals 92. A first output terminal 92 is connected to a first extending portion of the pair of extending portions 552, and a second output terminal 92 is connected to a second extending portion of the pair of extending portions 552. The two output terminals 92 are arranged side by side in the X direction. The two output terminals 92 are arranged at substantially the same position in the Z direction.

The signal terminal 93 is electrically connected to a drive circuit (driver) not shown. The signal terminal 93H is electrically connected to the pad 40P of the semiconductor element 40H via a connection member such as a bonding wire 110. The number of the signal terminals 93H is not particularly limited. The signal terminal 93H may include at least a terminal for applying a drive voltage to a gate electrode of the semiconductor element 40H. The semiconductor device 20 of the present embodiment includes two signal terminals 93H. One of the signal terminals 93H is a terminal for a gate electrode. The pads 40P for the gate electrodes of the two semiconductor elements 40H are electrically connected to the signal terminal 93H for the gate electrode. The signal terminal 93H is arranged at a position overlapping the notch 540 of the P wiring 54 in a plan view. In the signal terminal 93H, a joint portion with the bonding wire 110 faces not the front-surface metal body 52 but the insulating base material 51. The two signal terminals 93H are arranged side by side in the X direction.

The signal terminal 93H extends in the Y direction from the joint portion with the bonding wire 110, and protrudes outside the sealing body 30 from the vicinity of a center in the Z direction at the side surface 30c. At least a portion of the protruding portion of the signal terminal 93H extends in the same direction as the power supply terminal 91. The signal terminal 93H is arranged between the two P terminals 91P in the X direction. That is, the external connection terminals 90 protruding from the side surface 30c are arranged in an order of the N terminal 91N, the P terminal 91P, the two signal terminals 93H, the P terminal 91P, and the N terminal 91N in the X direction.

The signal terminal 93L is electrically connected to the pad 40P of the semiconductor element 40L via a connection member such as a bonding wire 110. The number of the signal terminals 93L is not particularly limited. The signal terminal 93L may include at least a terminal for applying a drive voltage to a gate electrode of the semiconductor element 40L. The semiconductor device 20 of the present embodiment includes four signal terminals 93L. One of the signal terminals 93L is a terminal for a gate electrode. The pads 40P for the gate electrodes of the two semiconductor elements 40L are electrically connected to the signal terminal 93L for the gate electrode. The signal terminal 93L is arranged at a position overlapping the notch 550 of the relay wiring 55 in a plan view. In the signal terminal 93L, a joint portion with the bonding wire 110 faces not the front-surface metal body 52 but the insulating base material 51. The four signal terminals 93L are arranged side by side in the X direction.

The signal terminal 93L extends in the Y direction from the joint portion with the bonding wire 110, and protrudes outside the sealing body 30 from the vicinity of a center in the Z direction at the side surface 30d. At least a portion of the protruding portion of the signal terminal 93L extends in the same direction as the output terminal 92. The signal terminal 93L is arranged between the two output terminals 92 in the X direction. That is, the external connection terminals 90 protruding from the side surface 30d are arranged in an order of the output terminal 92, the four signal terminals 93L, and the output terminal 92 in the X direction.

The drain electrode 40D of the semiconductor element 40 is joined to the front-surface metal body 52 via a joining material 100. The source electrode 40S of the semiconductor element 40 is joined to the conductive spacer 70 via a joining material 101. The conductive spacer 70 is joined to the front-surface metal body 62 via a joining material 102. The joint portion 81 is joined to the metal bodies 52 and 62 via a joining material 103. Among the external connection terminals 90, the P terminal 91P, the N terminal 91N, and the output terminal 92, which are main terminals, are joined to the corresponding front-surface metal bodies 52 and 62 via joining materials 104.

The joining materials 100 to 104 are joining materials having conductivity. For example, solder can be employed as the joining materials 100 to 104. An example of the solder is a multi-component lead-free solder containing Cu, Ni, or the like in addition to Sn. Instead of the solder, a sintered joining material such as sintered silver may be used. The P terminal 91P, the N terminal 91N, and the output terminal 92 may be directly joined to the corresponding front-surface metal bodies 52 and 62 without the interposition of the joining material 104. The P terminal 91P, the N terminal 91N, and the output terminal 92 may be directly joined to the front-surface metal bodies 52 and 62 by, for example, ultrasonic joining, friction stir welding, laser welding, or the like. When the joint portion 81 is provided separately from the substrates 50 and 60, the joint portion 81 may be directly joined to the front-surface metal bodies 52 and 62.

As described above, in the semiconductor device 20, the plurality of semiconductor elements 40 configuring the upper and lower arm circuit 9 for one phase are sealed by the sealing body 30. The sealing body 30 integrally seals the plurality of semiconductor elements 40, a portion of the substrate 50, a portion of the substrate 60, the plurality of conductive spacers 70, the arm connection portion 80, and a portion of each of the external connection terminals 90. The sealing body 30 seals the insulating base materials 51 and 61 and the front-surface metal bodies 52 and 62 of the substrates 50 and 60.

The semiconductor element 40 is disposed between the substrates 50 and 60 in the Z direction. The semiconductor element 40 is sandwiched by the substrates 50 and 60 disposed facing each other. Thereby, heat of the semiconductor element 40 can be dissipated to both sides in the Z direction. The semiconductor device 20 has a double-sided heat dissipation structure. The rear surface 50b of the substrate 50 is substantially flush with the front surface 30a of the sealing body 30. The rear surface 60b of the substrate 60 is substantially flush with the rear surface 30b of the sealing body 30. Since the rear surfaces 50b and 60b are exposed surfaces, heat dissipation properties can be improved.

### <Manufacturing Method>

Next, an example of a method for manufacturing the semiconductor device 20 will be described with reference to FIG. 10. In FIG. 10, the substrate 50 and the substrate 60 are shown facing each other for easy understanding of subsequent assembly.

First, the semiconductor elements 40, the substrates 50 and 60, the conductive spacers 70, the joint portion 81, and a lead frame 94 are prepared, respectively. The lead frame 94 includes the external connection terminals 90 as shown in FIG. 10. The lead frame 94 is formed by subjecting a metal plate to processing such as pressing. The external connection terminals 90 are supported by an outer peripheral frame 94b via tie bars 94a.

Next, the semiconductor elements 40, the joint portion 81, and the external connection terminals 90 are joined (connected) to the substrate 50. In addition, the conductive spacers 70 are joined to the semiconductor elements 40.

At this time, the lead frame 94 and the semiconductor elements 40 are arranged on the substrate 50. In addition, the conductive spacers 70 are arranged on the source electrodes 40S of the semiconductor elements 40. The lead frame 94 is arranged such that a portion of each of the external connection terminals 90 overlaps the substrate 50 in a plan view. Specifically, the P terminals 91P and the N terminals 91N are arranged so as to overlap the P wiring 54 of the front-surface metal body 52, and the output terminals 92 are arranged so as to overlap the relay wiring 55. In addition, the signal terminals 93H are arranged so as to overlap the insulating base material 51 exposed from the notches 540, and the signal terminals 93L are arranged so as to overlap the insulating base material 51 exposed from the notches 550.

Then, the drain electrodes 40D of the semiconductor elements 40 and the front-surface metal body 52 are joined by the joining material 100. The source electrodes 40S and the conductive spacers 70 are joined by the joining materials 101. The joint portion 81 and the front-surface metal body 52 are joined by the joining material 103. The P terminals 91P and the output terminals 92 are joined to the front-surface metal body 52 by the joining materials 104. For example, in a case of solder, joining can be performed collectively by reflow. FIG. 10 shows this joined state.

Next, the pads 40P of the semiconductor elements 40H and the signal terminals 93H are electrically connected by the bonding wires 110. Similarly, the pads 40P of the semiconductor elements 40L and the signal terminals 93L are electrically connected by the bonding wires 110.

Next, the substrate 60 is joined (connected). The source electrodes 40S of the semiconductor elements 40 and the front-surface metal body 62 are joined via the joining materials 102. The joint portion 81 and the front-surface metal body 62 are joined via the joining material 103. The N terminals 91N and the front-surface metal body 62 are joined via the joining materials 104. For example, in a case of solder, joining can be performed collectively by reflow.

Next, the sealing body 30 is molded by a transfer molding method. Although not shown, in the present embodiment, the sealing body 30 is molded so that the substrates 50 and 60 are completely covered, and cutting is performed after molding. The sealing body 30 is cut together with a portion of the rear-surface metal bodies 53 and 63 of the substrates 50 and 60. Thus, the rear surfaces 50b and 60b are exposed. The rear surface 50b is substantially flush with the front surface 30a of the sealing body 30, and the rear surface 60b is substantially flush with the rear surface 30b. The sealing body 30 may be molded in a state where the rear surfaces 50b and 60b are pressed against a cavity wall surface of a molding die and brought into close contact therewith. In this case, at a time when the sealing body 30 is molded, the rear surfaces 50b and 60b are exposed from the sealing body 30. Therefore, cutting after molding becomes unnecessary.

Next, in the lead frame 94, unnecessary portions such as the tie bars 94a and the outer peripheral frame 94b are removed. Thus, the semiconductor device 20 can be obtained.

### <Positional Relationship>

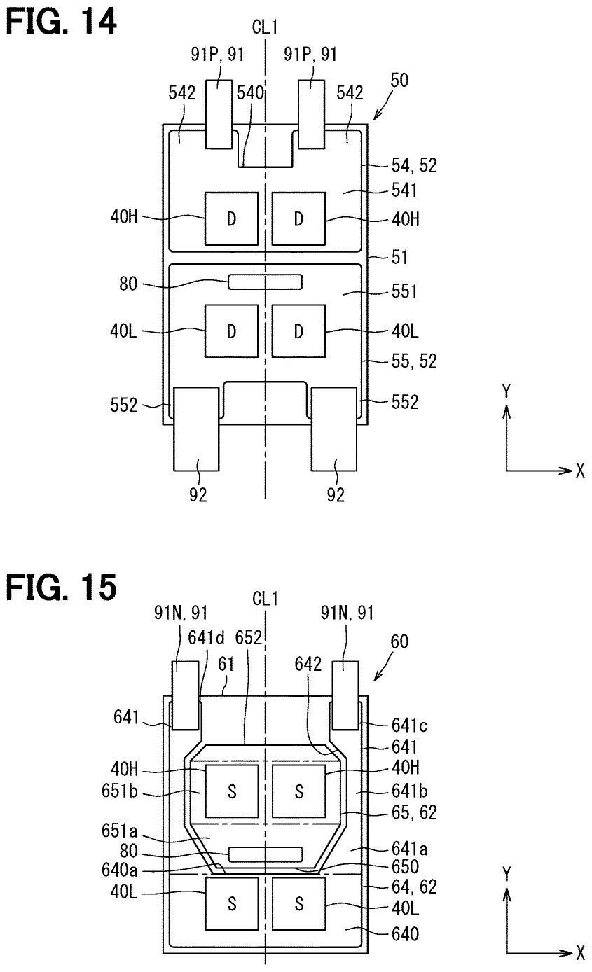

Next, a positional relationship among the semiconductor elements 40, the circuit patterns of the front-surface metal bodies 52 and 62, the arm connection portion 80, and the external connection terminals 90 connected to the circuit patterns will be described with reference to FIGS. 14 and 15. FIG. 14 is a diagram showing an arrangement of the circuit pattern of the front-surface metal body 52, the semiconductor elements 40, and the terminals. FIG. 15 is a diagram showing an arrangement of the circuit pattern of the front-surface metal body 62, the semiconductor elements 40, and the terminals. In FIGS. 14 and 15, for convenience, only the external connection terminals 90 connected to the circuit patterns are shown. In FIG. 14, D is shown in an arrangement region of the semiconductor elements 40 so that the main electrodes (drain electrodes 40D) connected to the front-surface metal body 52 can be easily understood. Similarly, in FIG. 15, S is shown in the arrangement region of the semiconductor elements 40 so that the main electrodes (source electrodes 40S) connected to the front-surface metal body 62 can be easily understood.

An imaginary line CL1 shown in FIG. 14 is an imaginary line passing through a midpoint of two semiconductor elements 40 configuring one arm. The imaginary line CL1 passes through a midpoint (center) in an arrangement direction of the two semiconductor elements 40 and extends in the Y direction. The imaginary line CL1 is, for example, a line passing through a midpoint of the two semiconductor elements 40H. A line passing through a midpoint of the semiconductor elements 40L may be used instead of the semiconductor elements 40H.

As shown in FIG. 14, an arrangement of the two semiconductor elements 40H is substantially line-symmetric with respect to the imaginary line CL1. Similarly, an arrangement of the two semiconductor elements 40L is also substantially line-symmetric with respect to the imaginary line CL1. Here, “substantially line-symmetric” can allow for an error of a degree of manufacturing variation. The circuit pattern of the front-surface metal body 52 is also substantially line-symmetric with respect to the imaginary line CL1. That is, each of the P wiring 54 and the relay wiring 55 is substantially line-symmetric with respect to the imaginary line CL1.

An arrangement of the arm connection portions 80 connected to the relay wiring 55 is also substantially line-symmetric with respect to the imaginary line CL1. An arrangement of the external connection terminals 90 connected to the front-surface metal body 52 is also substantially line-symmetric with respect to the imaginary line CL1. That is, an arrangement of the two P terminals 91P is also substantially line-symmetric with respect to the imaginary line CL1. An arrangement of the two output terminals 92 is also substantially line-symmetric with respect to the imaginary line CL1.

Similar to FIG. 14, the imaginary line CL1 is also shown in FIG. 15. The arrangement of the semiconductor elements 40H and 40L is similar to that in FIG. 14. As shown in FIG. 15, the circuit pattern of the front-surface metal body 62 is also substantially line-symmetric with respect to the imaginary line CL1. That is, each of the N wiring 64 and the relay wiring 65 is substantially line-symmetric with respect to the imaginary line CL1. The arrangement of the arm connection portions 80 connected to the relay wiring 65 is also substantially line-symmetric with respect to the imaginary line CL1, similar to FIG. 14. An arrangement of the two N terminals 91N which are the external connection terminals 90 connected to the front-surface metal body 62 is also substantially line-symmetric with respect to the imaginary line CL1.

### <Circuit Pattern>

Next, the circuit pattern of the front-surface metal body 62 will be described in more detail with reference to FIG. 15. An alternate long and short dash line shown in FIG. 15 indicates a boundary of each region.

As described above, the front-surface metal body 62 of the substrate 60 has the N wiring 64 and the relay wiring 65. The N wiring 64 has the base portion 640 and the pair of extending portions 641. The pair of extending portions 641 extend from the base portion 640 in the Y direction and toward the side surface 30c of the sealing body 30. The N wiring 64 defines an outer profile of the front-surface metal body 62. The relay wiring 65 is sandwiched by the pair of extending portions 641. The relay wiring 65 is arranged within the notch 642 of the N wiring 64.

As shown in FIG. 15, the relay wiring 65 has an end portion 650 as one end in the Y direction. The end portion 650 is an end portion on a side of the base portion 640 in the Y direction. On the other hand, the base portion 640 of the N wiring 64 has a facing side 640a facing the end portion 650. The facing side 640a is a portion of the base portion 640 between the pair of extending portions 641.

The relay wiring 65 of the present embodiment has a reduced-width portion 651a. The reduced-width portion 651a includes the end portion 650. The reduced-width portion 651a is a portion in a predetermined range in the Y direction from the end portion 650. A length in the X direction, that is, a width, of the reduced-width portion 651a is minimum at the end portion 650.

The width of the reduced-width portion 651a may be reduced stepwise, for example, for every predetermined length in the Y direction. That is, an end portion of the reduced-width portion 651a in the X direction may change in a stepped shape. In the present embodiment, the closer to the base portion 640, the shorter the length of the reduced-width portion 651a in the X direction. That is, the width of the reduced-width portion 651a continuously reduces toward the base portion 640. The arm connection portion 80 is arranged on the reduced-width portion 651a.

The relay wiring 65 may have only the reduced-width portion 651a including the end portion 650. In this case, the semiconductor element 40H is also arranged on the reduced-width portion 651a. The relay wiring 65 of the present embodiment has a constant-width portion 651b. The constant-width portion 651b continues to the reduced-width portion 651a, and is a portion having a constant width over a predetermined range in the Y direction. The semiconductor element 40H is arranged on the constant-width portion 651b.

The relay wiring 65 of the present embodiment further has a reduced-width portion 651c. The reduced-width portion 651c includes an end portion 652 opposite to the end portion 650. The reduced-width portion 651c is opposite to the reduced-width portion 651a and continues to the constant-width portion 651b. A width of the reduced-width portion 651c is minimum at the end portion 652. In the present embodiment, the width of the reduced-width portion 651c continuously reduces toward the end portion 652. In the relay wiring 65, the widths of the reduced-width portions 651a and 651c are narrower as a distance from the constant-width portion 651b increases.

In the present embodiment, a gap between the N wiring 64 and the relay wiring 65 is substantially constant over an entire area of the end portion 650. The extending portions 641 of the N wiring 64 are patterned such that a gap between the extending portions 641 and the relay wiring 65 is substantially constant. Each of the extending portions 641 has an expanded-width portion 641a, a constant-width portion 641b, and an expanded-width portion 641c.

The expanded-width portion 641a continues to the base portion 640, and is a portion in a predetermined range in the Y direction from a boundary with the base portion 640. A length in the X direction, that is, a width, of the expanded-width portion 641a is maximum at the boundary with the base portion 640. The width of the expanded-width portion 641a of the present embodiment continuously expands toward the base portion 640. The constant-width portion 641b continues to the expanded-width portion 641a, and is a portion having a constant width over a predetermined range in the Y direction. The constant-width portion 641b faces the constant-width portion 651b of the relay wiring 65.

The expanded-width portion 641c is opposite to the expanded-width portion 641a and continues to the constant-width portion 641b. The expanded-width portion 641a extends to a position closer to the side surface 30c than the reduced-width portion 651c. The expanded-width portion 641c includes a tip portion 641d of the extending portion 641. A width of the expanded-width portion 641c is maximum at the tip portion 641d. In the expanded-width portion 641c, a width of an arbitrary first position is equal to or greater than a width of a second position farther from the tip portion 641d than the first position. In the present embodiment, the width of the expanded-width portion 641c continuously expands toward the tip portion 641d at a portion facing the reduced-width portion 651c. In the expanded-width portion 641c, a portion on a side of the tip portion 641d with respect to the facing portion has a constant width. In the N wiring 64, widths of a portion of the expanded-width portion 641c and the expanded-width portion 641a are wider as a distance from the constant-width portion 641b increases.

### <Current Path>

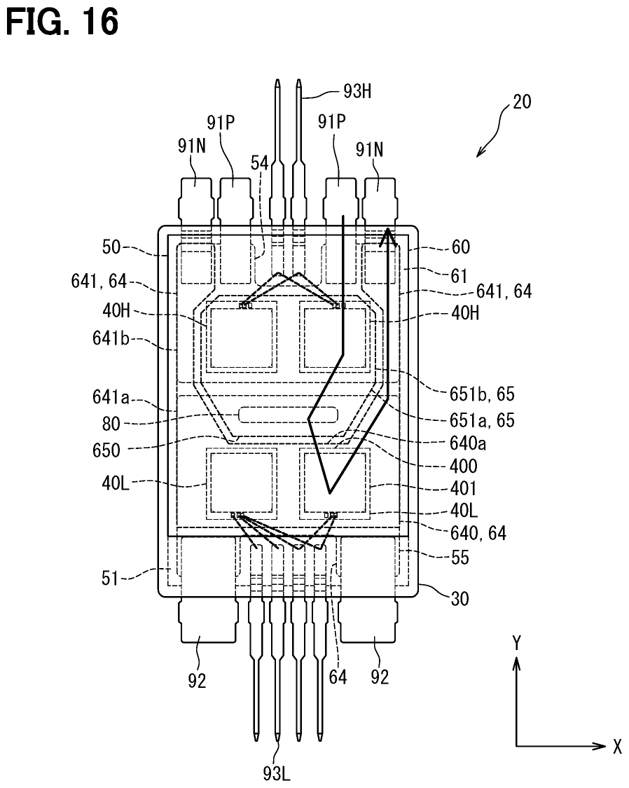

Next, a current path will be described with reference to FIG. 16. FIG. 16 is a diagram showing a PN current loop in the semiconductor device 20 of the present embodiment. The PN current loop refers to a loop shape of a current path from the P terminal 91P to the N terminal 91N.

In considering an inductance, a PN current loop flowing from the P terminal 91P to the N terminal 91N through the P wiring 54, the semiconductor element 40H, the relay wiring 65, the arm connection portion 80, the relay wiring 55, the semiconductor element 40L, and the N wiring 64 in this order, is taken into account. For this reason, a continuous solid line is shown from the P terminal 91P to the N terminal 91N so that the PN current loop can be easily understood. In practice, the semiconductor elements 40H and 40L are controlled so as not to be turned on at the same time. For convenience, only a current path for one of the semiconductor elements 40H and one of the semiconductor elements 40L is shown, but the same applies to another one of the semiconductor elements 40H and another one of the semiconductor elements 40L.

In the semiconductor device 20 of the present embodiment, as described above, the N wiring 64 and the relay wiring 65 are patterned to satisfy a predetermined positional relationship with the semiconductor element 40L. By this positional relationship, as shown in FIG. 16, the N wiring 64 (extending portion 641) also exists above one side 400 of the semiconductor element 40L in a plan view. The side 400 is a side facing the relay wiring 65. Thus, a current enters from the side 400 of the semiconductor element 40L, and the current exits from the same side 400. In the current flowing from the semiconductor element 40L toward the N terminal 91N, a Y-direction component increases particularly in the vicinity of the semiconductor element 40L.

In this way, the current flowing through the N wiring 64 approaches the relay wiring 65, and the current path provided by the N wiring 64, that is, the current path between the semiconductor element 40L and the N terminal 91N is shortened. Therefore, the PN current loop is small. The PN current loop is also small in the Z direction. The P wiring 54 and the N wiring 64 face each other in the Z direction. Further, the relay wiring 55 and the N wiring 64 face each other in the Z direction. Since the PN current loop is small in this way, the inductance of a main circuit wiring can be reduced.

### <Adhesion Portion on D-Side Substrate>

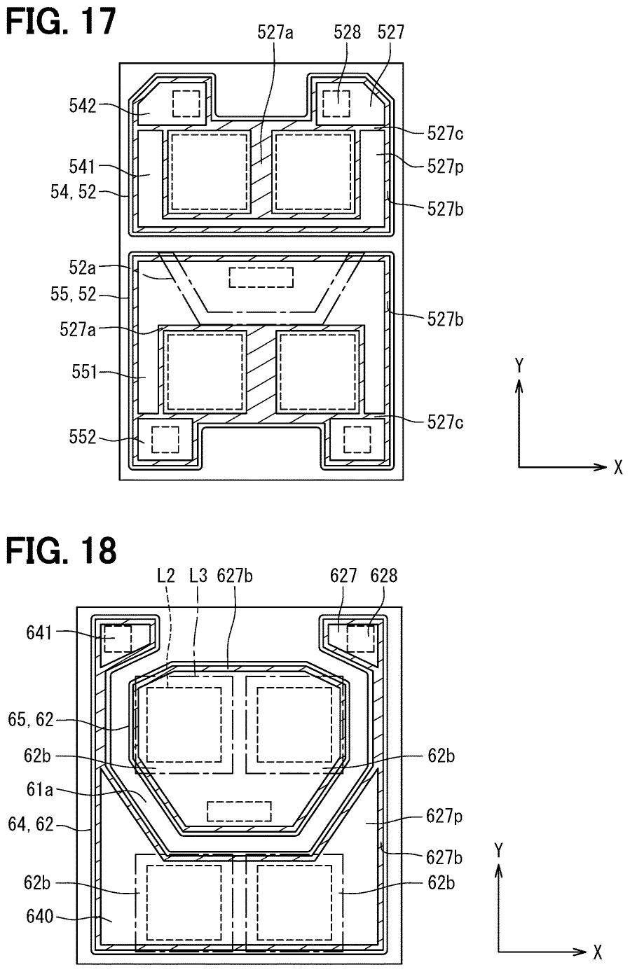

As shown in FIGS. 9 and 17, in the substrate 50 on the D side, a portion of the front-surface metal body 52 that is not in contact with the insulating base material 51 is divided into an adhesion portion 527 and a non-adhesion portion 528. The adhesion portion 527 is a region that is in contact with the sealing body 30 as a contact portion, and is a region that is in close contact with and sealed by the sealing body 30. The non-adhesion portion 528 is a region that is not in contact with the sealing body 30. A portion surrounded by a dotted line in FIG. 17 indicates the non-adhesion portion 528. Specifically, in the front-surface metal body 52, joined portions with the semiconductor elements 40, joined portions with the P terminals 91P, joined portions with the output terminals 92, and a joined portion with the arm connection portion 80 correspond to the non-adhesion portion 528.

The adhesion portion 527 of the substrate 50 on the D side includes a high-adhesion portion having an increased degree of adhesion to the sealing body 30, and a low-adhesion portion 527p having a lower degree of adhesion to the sealing body 30 than the high-adhesion portion. In other words, the adhesion portion 527 includes the high-adhesion portion having higher adhesion to the sealing body 30 and the low-adhesion portion 527p having lower adhesion to the sealing body 30 than the adhesion of the high-adhesion portion to the sealing body 30. A surface roughness of the high-adhesion portion is rougher than a surface roughness of the low-adhesion portion 527p. Therefore, a contact area with the sealing body 30 is larger in the high-adhesion portion, and an adhesion force of the high-adhesion portion to the sealing body 30 is higher than that of the low-adhesion portion 527p. Thus, peeling of the sealing body 30 is less likely to occur at the high-adhesion portion.

The high-adhesion portion includes an element annular portion 527a, a metal body annular portion 527b, and a terminal annular portion 527c. The element annular portion 527a, the metal body annular portion 527b, and the terminal annular portion 527c may have a portion that is integral with each other. The term “annular” as used herein refers to a portion surrounding a region and is not limited to a circular shape.

The element annular portion 527a has a shape extending in an annular shape along an outer profile of the semiconductor elements 40H and 40L, and surrounds the semiconductor elements 40H and 40L. That is, the element annular portion 527a has a rectangular shape extending along an outer profile of the non-adhesion portion 528 at the joined portion to the semiconductor elements 40. In a region where the two semiconductor elements 40H are arranged side by side in the P wiring 54, the two element annular portions 527a are integrated. Similarly, in a region where the two semiconductor elements 40L are arranged side by side in the relay wiring 55, the two element annular portions 527a are integrated.

The metal body annular portion 527b has a shape extending in an annular shape along an outer profile of the front-surface metal body 52. That is, the metal body annular portion 527b has a shape extending in an annular shape along outer profiles of the P wiring 54 and the relay wiring 55. The metal body annular portion 527b along the outer profile of the P wiring 54 surrounds all the low-adhesion portions 527p on the P wiring 54. The metal body annular portion 527b along the outer profile of the relay wiring 55 surrounds all the low-adhesion portions 527p on the relay wiring 55.

The terminal annular portion 527c has a shape extending in an annular shape along an outer profile of a portion of the front-surface metal body 52 to which the power supply terminals 91 and the output terminals 92 are connected, and surrounds terminal connection portions. That is, the terminal annular portion 527c has a shape surrounding the extending portions 542 and the extending portions 552. A portion of the terminal annular portion 527c is formed integrally with a portion of the metal body annular portion 527b. A portion of the terminal annular portion 527c is formed integrally with a portion of the element annular portion 527a.

Each of the low-adhesion portions 527p is surrounded by a corresponding one of the element annular portion 527a, the metal body annular portion 527b, and the terminal annular portion 527c, and arranged inside the annular portion. In the substrate 50 on the D side, an area of the high-adhesion portions is smaller than an area of the low-adhesion portions 527p. That is, a total area of the element annular portion 527a, the metal body annular portion 527b, and the terminal annular portion 527c is smaller than the area of the low-adhesion portions 527p. Further, also in the P wiring 54, it can be said that the area of the high-adhesion portion is smaller than the area of the low-adhesion portion 527p. Also in the relay wiring 55, it can be said that the area of the high-adhesion portion is smaller than the area of the low-adhesion portion 527p.

The high-adhesion portion is arranged between portions of the front-surface metal body 52 having different potentials, that is, between portions having different potentials. That is, the P wiring 54 and the relay wiring 55 correspond to the portions having different potentials. A portion of the metal body annular portion 527b surrounding the P wiring 54 that faces the relay wiring 55 corresponds to the high-adhesion portion arranged between the portions having different potentials. Further, a portion of the metal body annular portion 527b surrounding the relay wiring 55 that faces the P wiring 54 also corresponds to the high-adhesion portion arranged between the portions having different potentials.

### <Adhesion Portion on S-Side Substrate>

As shown in FIGS. 9 and 18, also in the substrate 60 on the S side, similar to the substrate 50 on the D side, a portion of the front-surface metal body 62 that is not in contact with the insulating base material 61 is divided into an adhesion portion 627 and a non-adhesion portion 628. The adhesion portion 627 is a region that is in contact with the sealing body 30 as a contact portion, and is a region that is in close contact with the sealing body 30, and the non-adhesion portion 628 is a region that is not in contact with the sealing body 30. A portion surrounded by a dotted line in FIG. 18 indicates the non-adhesion portion 628. Specifically, in the front-surface metal body 62, the joined portions to the semiconductor elements 40, the joined portions to the N terminals 91N, and the joined portion to the arm connection portion 80 correspond to the non-adhesion portion 628.

The adhesion portion 627 of the substrate 60 on the S side includes a high-adhesion portion having an increased degree of adhesion with the sealing body 30, and a low-adhesion portion 627p having a lower degree of adhesion with the sealing body 30 than the high-adhesion portion. In other words, the adhesion portion 627 includes the high-adhesion portion having higher adhesion to the sealing body 30 and the low-adhesion portion 627p having lower adhesion to the sealing body 30 than the adhesion of the high-adhesion portion to the sealing body 30. Similar to the substrate 50 on the D side, a surface roughness of the high-adhesion portion is rougher than a surface roughness of the low-adhesion portion 627p, so that an adhesion force with the sealing body 30 is high in the high-adhesion portion.

The high-adhesion portion includes a metal body annular portion 627b. The metal body annular portion 627b has a shape extending in an annular shape along an outer profile of the front-surface metal body 62. That is, the metal body annular portion 627b has a shape extending in an annular shape along outer profiles of the N wiring 64 and the relay wiring 65. The metal body annular portion 627b along the outer profile of the N wiring 64 surrounds all the low-adhesion portions 627p on the N wiring 64. The metal body annular portion 627b along the outer profile of the relay wiring 65 surrounds all the low-adhesion portions 627p on the relay wiring 65.

The metal body annular portion 627b also functions as an element annular portion surrounding the semiconductor elements 40H and 40L. The metal body annular portion 627b also functions as a terminal annular portion of the front-surface metal body 62 surrounding the power supply terminals 91. Although the metal body annular portion 627b has a shape extending linearly at least at a part, linear portions facing each other in the annular shape may be adjacent to form a single line. For example, when a separation distance between facing linear portions is short, such as a portion surrounding the extending portion 641, two lines may be in contact with each other to form a single line.

The high-adhesion portion is arranged between portions of the front-surface metal body 62 having different potentials, that is, between the portions having different potentials. That is, the N wiring 64 and the relay wiring 65 correspond to the portions having different potentials. A portion of the metal body annular portion 627b surrounding the N wiring 64 and facing the relay wiring 65 corresponds to the high-adhesion portion arranged between the portions having different potentials. Further, a portion of the metal body annular portion 627b surrounding the relay wiring 65 and facing the N wiring 64 also corresponds to the high-adhesion portion arranged between the portions having different potentials.

### <Exposed Facing Portion>

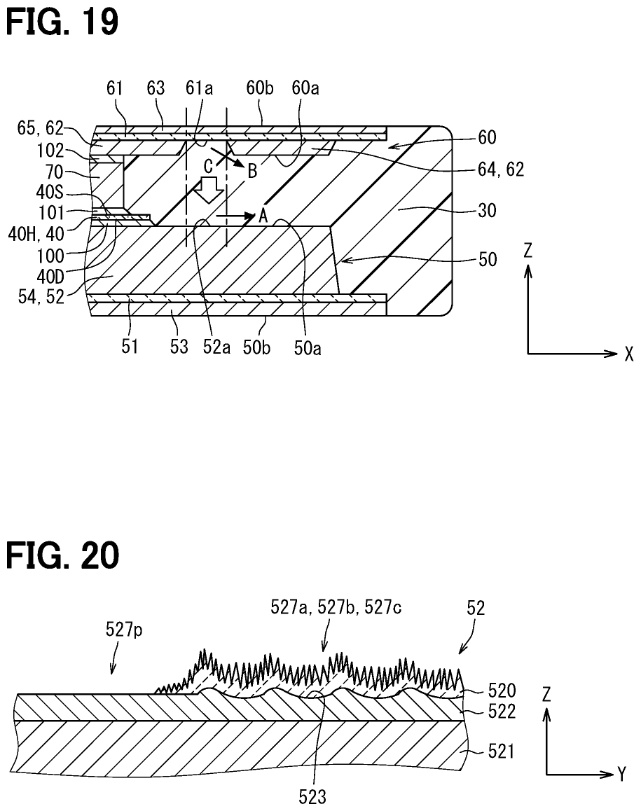

As shown in FIGS. 18 and 19, a portion of the substrate 60 on the S side (one of the substrates) in which the insulating base material 61 is exposed without the front-surface metal body 62 being provided is referred to as an exposed portion 61a. As shown in FIGS. 17 and 19, in the front-surface metal body 52 of the substrate 50 on the D side (the other of the substrates), a portion facing the exposed portion 61a is referred to as an exposed facing portion 52a. A region surrounded by an alternate long and short dash line shown in FIG. 19 indicates the exposed facing portion 52a of the relay wiring 55. The exposed portion 61a corresponding to the exposed facing portion 52a of the relay wiring 55 is a portion of the insulating base material 61 between the N wiring 64 and the relay wiring 65.

An illustration of an exposed facing portion of the P wiring 54 is omitted. Further, the substrate 60 on the S side corresponds to one of the first substrate and the second substrate, and the substrate 50 on the D side corresponds to the other of the first substrate and the second substrate. Also in the substrate 50 on the D side, an exposed portion in which the insulating base material 51 is exposed exists. Also in the front-surface metal body 62 on the S side, an exposed facing portion facing the exposed portion on the D side also exists.

At least a portion of the low-adhesion portion 527p of the substrate 50 on the D side is formed in the exposed facing portion 52a. For example, a portion surrounded by an alternate long and short dash line in FIG. 17 is the portion of the low-adhesion portion 527p corresponding to the exposed facing portion 52a. In the exposed facing portion 52a, an area where the low-adhesion portion 527p is formed is larger than an area where the high-adhesion portion is formed.

In the exposed facing portion 52a of the front-surface metal body 52, basically, not the high-adhesion portion but the low-adhesion portion 527p is formed. However, exceptionally, in a region between the portions having different potentials, there is a portion where the high-adhesion portion is formed even in the exposed facing portion 52a. For example, of the annular shape along the outer profile of the P wiring 54 or the relay wiring 55, in the linear region located between the portions having different potentials and in a portion corresponding to the exposed facing portion 52a, not the low-adhesion portion 527p but the high-adhesion portion is formed. That is, even in the region corresponding to the exposed facing portion 52a, a priority is given to forming the high-adhesion portion in the region between the portions having different potentials.

In the region extending in the annular shape along the outer profile of the front-surface metal body 52, exceptionally, there is a portion where the high-adhesion portion is formed even in the exposed facing portion 52a. For example, of the annular shape along the outer profile of the P wiring 54 or the relay wiring 55, in the linear region which is also a portion of the exposed facing portion 52a, not the low-adhesion portion 527p but the high-adhesion portion is formed. That is, even in the region corresponding to the exposed facing portion 52a, a priority is given to forming the metal body annular portion 527b.

Further, in a region extending of the annular shape along the outer profile of the semiconductor elements 40H and 40L, exceptionally, there is a portion where the high-adhesion portion is formed even in the exposed facing portion 52a. That is, even in a region corresponding to the exposed facing portion 52a, a priority is given to forming the terminal annular portion 527c.

### <Roughening of High-Adhesion Portion>

The high-adhesion portions on the D side and the S side described above are formed by the same method. In the following description, the high-adhesion portion on the D side will be described, and the description of the high-adhesion portion on the S side will be incorporated by reference.

As shown in FIG. 20, the front-surface metal body 52 has a base material 521, a metal film 522 provided on a surface of the base material 521 and an uneven oxide film 520. The base material 521 forms a main portion of the front-surface metal body 52. The base material 521 is formed using, for example, a Cu-based material. The metal film 522 is formed to include a material having a higher wettability to solder than the base material 521. A portion of the base material 521 on which the metal film 522 is not formed corresponds to the exposed portion described above. The uneven oxide film 520 is formed in the region of the high-adhesion portion described above, and provides the high-adhesion portion.

The uneven oxide film 520 is formed by irradiating the metal film 522 with a laser beam. The metal film 522 has an underlying film whose main component is nickel (Ni), and an overlying film whose main component is gold (Au). In the present embodiment, an electroless Ni plating film containing phosphorous (P) is employed as the underlying film. Of the metal film 522, the overlying Au film at a portion where the uneven oxide film 520 is to be formed is removed by irradiation with the laser beam when the uneven oxide film 520 is formed. The uneven oxide film 520 is a film of an oxide whose main component is Ni.

Recessed portions 523 on the surface of the metal film 522 are formed by irradiation with a pulsed laser beam. One recessed portion 523 is formed by each pulse. The uneven oxide film 520 is formed through melting, vaporizing and deposition of a surface layer portion of the metal film 522 due to the irradiation with the laser beam. The uneven oxide film 520 is an oxide film derived from the metal film 522. The uneven oxide film 520 is a film of an oxide of a main component metal (e.g., Ni) of the metal film 522. The uneven oxide film 520 is formed following unevenness on the surface of the metal film 522 having the recessed portions 523. Unevenness is formed on a surface of the uneven oxide film 520 at a pitch finer than a width of the recessed portions 523. That is, a very fine unevenness (roughened portion) is formed.

Such an uneven oxide film 520 can be formed by the following steps. First, the front-surface metal body 52 in which the metal film 522 is formed on the base material 521 is irradiated with a pulsed laser beam to melt and evaporate the surface of the metal film 522.

At this time, by relatively moving a light source of the laser beam and the front-surface metal body 52, the laser beam is scanned and sequentially irradiated onto a plurality of positions. The recessed portion 523 is formed on the surface of the metal film 522 by irradiating the laser beam to melt and vaporize the surface of the metal film 522. Of the metal film 522, an average thickness of a portion irradiated with the laser beam becomes thinner than an average thickness of a portion not irradiated with the laser beam. Further, a plurality of the recessed portions 523 formed corresponding to spots of the laser beam are continuous, and form, for example, a scale shape. A spot is an irradiation range by one pulse. For example, the laser beam is scanned such that spots of the laser beam adjacent to each other in the X direction partially overlap each other, and spots of the laser beam adjacent to each other in the Y direction partially overlap each other.

Next, the melted portion of the metal film 522 is solidified. Specifically, the melted and vaporized metal film 522 is deposited on the portion irradiated with the laser beam and a peripheral portion thereof. By depositing the melted and vaporized metal film 522 in this way, the uneven oxide film 520 is formed on the surface of the metal film 522.

Since very fine unevenness is formed on the surface of the uneven oxide film 520 formed as described above, the sealing body 30 gets entangled, producing an anchor effect. Furthermore, a contact area with the sealing body 30 increases. Therefore, the adhesion force of the front-surface metal body 52 to the sealing body 30 can be increased. A similar uneven oxide film is formed on the front-surface metal body 62 on the S side, and the adhesion force of the front-surface metal body 62 is increased.

Here, since the front-surface metal bodies 52 and 62 and the sealing body 30 have different linear expansion coefficients with respect to a temperature, there is a concern that the above-described adhesion may be damaged and peeling may occur. Since electrical insulation properties of air are inferior to those of the sealing body 30, electrical insulation properties of the front-surface metal bodies 52 and 62 decrease at a location where peeling occurs as described above. As a result, there is a concern that an electrical leak path may be formed between the portions having different potentials, such as between the P wiring 54 and the relay wiring 55, or between the N wiring 64 and the relay wiring 65. When the location of the peeling is an electrical connection portion such as solder, stress concentrates on the electrical connection portion, causing a concern that distortion or damage may occur in the electrical connection portion. Therefore, in the present embodiment, the peeling is suppressed by the high-adhesion portion to solve the above concern.

### <Effects Regarding High-Adhesion Portion>

If all the low-adhesion portions 527p and 627p were to be replaced with high-adhesion portions contrary to the present embodiment, an area to be roughened by a laser beam would increase, increasing processing costs. In view of this point, in the present embodiment, in addition to the high-adhesion portion, the low-adhesion portions 527p and 627p are also formed in the contact portions of the front-surface metal bodies 52 and 62 that are in contact with the sealing body 30, which are adhesion portions. Therefore, compared to a case where the entire adhesion portion is formed as the high-adhesion portion, the processing costs can be significantly reduced. Furthermore, since the high-adhesion portion is arranged in the location between the portions having different potentials of the front-surface metal bodies 52 and 62, peeling of the sealing body 30 in the location between the portions having different potentials can be sufficiently suppressed. Thus, a concern that a leak path is formed between the portions having different potentials can be sufficiently suppressed. As described above, in the semiconductor device 20 according to the present embodiment, it is possible to achieve both a reduction in manufacturing costs and an improvement in reliability.

In the present embodiment, the high-adhesion portion includes the metal body annular portions 527b and 627b extending in the annular shape along the outer profile of the front-surface metal bodies 52 and 62. According to this, even if peeling occurs inside surrounded by the metal body annular portions 527b and 627b, the location of the peeling is surrounded by the metal body annular portions 527b and 627b where no peeling occurs. Thus, a concern that a leak path is formed from the peeling location can be further reduced. In addition, a concern that a leak path is formed between the front-surface metal body 52 and the rear-surface metal body 53 can also be reduced.

In the present embodiment, the high-adhesion portion includes the element annular portion 527a extending in the annular shape along the outer profile of the semiconductor elements 40H and 40L. According to this, it is possible to reduce a concern that stress concentration due to peeling described above occurs at an electrical connection portion (for example, solder) between the semiconductor elements 40H and 40L and the front-surface metal body 52. Thus, a concern that distortion or damage occurs in the electrical connection portions of the semiconductor elements 40H and 40L can be reduced.

In the present embodiment, the high-adhesion portion includes the terminal annular portion 527c extending in an annular shape so as to surround a connection portion between the front-surface metal body 52 and the external connection terminal 90. According to this, it is possible to reduce a concern that stress concentration due to peeling described above occurs at an electrical connection portion (for example, solder) between the external connection terminal 90 and the front-surface metal body 52. Thus, a concern that distortion or damage occurs in the electrical connection portion of the external connection terminal 90 can be reduced.

In the present embodiment, the high-adhesion portion and the low-adhesion portion are formed on both the substrate 50 on the D side (first substrate) and the substrate 60 on the S side (second substrate). A concern that a leak path is formed between the front-surface metal body 52 on the D side and the front-surface metal body 62 on the S side can also be further reduced.

In the present embodiment, at least a portion of the high-adhesion portion has a shape extending in the annular shape, and at least a portion of the low-adhesion portions 527p and 627p is surrounded by the high-adhesion portion. According to this, even if peeling occurs in the low-adhesion portions 527p and 627p surrounded by the high-adhesion portion, the location of the peeling is surrounded by the high-adhesion portion where no peeling occurs. Thus, a concern that a leak path is formed from the location of the peeling in the low-adhesion portions 527p and 627p can be further reduced.

In the present embodiment, in each of the substrates 50 and 60, that is, in a single substrate 50, 60, an area of the high-adhesion portion is smaller than an area of the low-adhesion portions 527p, 627p. Therefore, reduction in processing costs required for forming the high-adhesion portion can be promoted.

### <Effects Regarding Exposed Facing Portion>

If, contrary to the present embodiment, a high-adhesion portion is formed over an entirety of the exposed facing portion 52a, the following concerns arise. That is, due to a difference in linear expansion coefficient between the sealing body 30 and the front-surface metal body 52, a contact surface of the sealing body 30 being in contact with the front-surface metal body 52 is pulled by the front-surface metal body 52 in accordance with a temperature change. When the contact surface is the high-adhesion portion, a force with which the sealing body 30 is pulled from the front-surface metal body 52 becomes strong. The pulling force acts in the X direction as indicated by an arrow A in FIG. 19.

On the other hand, a contact surface of the sealing body 30 being in contact with the exposed portion 61a is pulled in the Z direction in addition to the X direction as indicated by an arrow B in FIG. 19, due to occurrence of the pulling force A. That is, a pulling force in the Z direction acts on a contact surface of the sealing body 30 being contact with the exposed portion 61a, as indicated by an arrow C. As a result, there is a concern of damage such as cracking occurs in the insulating base material 61. If an attempt is made to increase strength by increasing a thickness dimension of the insulating base material 61 as a countermeasure, the heat dissipation function of the substrate 60 will be degraded.

In view of this point, in the present embodiment, at least a portion of the low-adhesion portion 527p is formed in the exposed facing portion 52a. Therefore, compared to a case where an entirety of the exposed facing portion 52a is formed as the high-adhesion portion, the pulling force A generated at the exposed facing portion 52a can be reduced, and the pulling force C acting on the exposed portion 61a can be reduced. Thus, a concern that cracking occurs in the insulating base material 61 can be reduced without increasing the thickness dimension of the insulating base material 61. That is, cracking damage can be suppressed without causing a decrease in the heat dissipation function of the insulating base material 61.

In the present embodiment, in the exposed facing portion 52a, the area where the low-adhesion portion 527p is formed is larger than the area where the high-adhesion portion is formed. Therefore, reduction of the pulling force A generated at the exposed facing portion 52a can be made sufficiently large, and a damage suppression effect of the insulating base material 61 can be sufficiently secured.

In the present embodiment, in the region between the portions having different potentials of the substrate 50 on the D side (second substrate), there is a portion where the high-adhesion portion is formed even in the exposed facing portion 52a. Therefore, the above-described effect of suppressing peeling of the sealing body 30 between the portions having different potentials by the high-adhesion portion and suppressing a concern that a leak path is formed between the portions having different potentials is exhibited. Even so, since the entirety of the exposed facing portion 52a is not formed as the high-adhesion portion, but the low-adhesion portion 527p is formed at least partially, a damage suppression effect of the insulating base material 61 is also exhibited.

In the present embodiment, in the region extending in the annular shape along the outer profile of the front-surface metal body 52 of the substrate 50 on the D side, there is a portion where the high-adhesion portion is formed even in the exposed facing portion 52a. Therefore, even if peeling occurs inside surrounded by the metal body annular portion 527b, the above-described effect that a concern that the leak path is formed from the location of the peeling can be reduced by the metal body annular portion 527b is exhibited. Even so, since the low-adhesion portion 527p is formed on at least a portion of the exposed facing portion 52a, a damage suppression effect of the insulating base material 61 is also exhibited.

In the present embodiment, in the region extending in the annular shape along the outer profile of the semiconductor elements 40H and 40L of the substrate 50 on the D side, there is a portion where the high-adhesion portion is formed even in the exposed facing portion 52a. Therefore, the above-described effect of reducing a concern that stress concentration occurs at an electrical connection portion between the semiconductor elements 40H and 40L and the front-surface metal body 52 is exhibited. Even so, by forming the low-adhesion portion 527p in at least a portion of the exposed facing portion 52a, a damage suppression effect of the insulating base material 61 is also exhibited.

### Second Embodiment

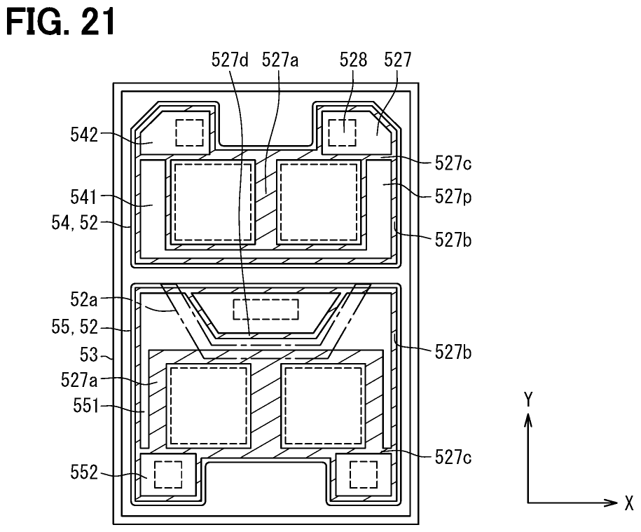

In the first embodiment, line widths of the element annular portion 527a, the metal body annular portion 527b, and the terminal annular portion 527c are formed to be the same. On the other hand, in the present embodiment, as shown in FIG. 21, the line width of the element annular portion 527a formed in the relay wiring 55 is larger than the line widths of the metal body annular portion 527b and the terminal annular portion 527c.

However, as a result of increasing the line width of the element annular portion 527a in the present embodiment, an area of the high-adhesion portion occupying the exposed facing portion 52a increases. Therefore, from a viewpoint of improving a damage suppression effect of the insulating base material 61 by reducing an area of the high-adhesion portion occupying the exposed facing portion 52a, it is desirable to form an entirety of the element annular portion 527a so as not to overlap the exposed facing portion 52a as in the first embodiment. Conversely to the present embodiment, a line width of the metal body annular portion 527b may be thicker than the line width of the element annular portion 527a.

In the first embodiment, an entire region between the element annular portion 527a and the metal body annular portion 527b in the relay wiring 55 is the low-adhesion portion 527p. On the other hand, in the present embodiment, as shown in FIG. 21, a non-annular portion 527d which is the high-adhesion portion is also formed in a region between the element annular portion 527a and the metal body annular portion 527b. In the example shown in FIG. 21, an entirety of the non-annular portion 527d is formed so as not to overlap the exposed facing portion 52a, but a portion of the non-annular portion 527d may overlap the exposed facing portion 52a. The non-annular portion 527d has a non-annular shape, and both ends of the non-annular portion 527d are connected to the metal body annular portion 527b.

In the first embodiment, the rear-surface metal body 53 and the front-surface metal body 52 have the same size in a plan view. On the other hand, in the present embodiment, the rear-surface metal body 53 is larger than the front-surface metal body 52, and an entire outer edge of the rear-surface metal body 53 protrudes from the front-surface metal body 52 in a plan view. As described above, in the present embodiment, the line width of the annular portion is arbitrarily set, and the non-annular portion 527d is provided. Other configurations are the same as those of the first embodiment. Therefore, also in the present embodiment, the same effects as those of the first embodiment are exhibited.

### Third Embodiment

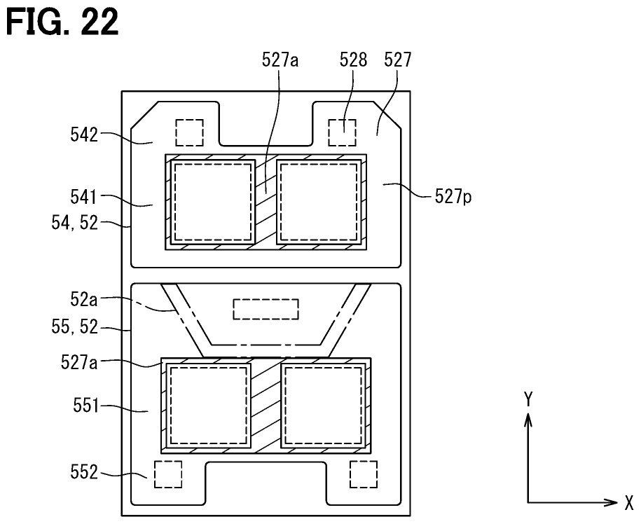

In the present embodiment, as shown in FIG. 22, the element annular portion 527a is formed, but the metal body annular portion 527b, the terminal annular portion 527c, and the non-annular portion 527d are eliminated. The element annular portion 527a, the terminal annular portion 527c, and the non-annular portion 527d may be eliminated while the metal body annular portion 527b is formed. According to the present embodiment, an area of the high-adhesion portion occupying the front-surface metal body 52 can be made smaller than those in the first and second embodiments. Thus, processing costs for roughening by a laser or the like can be further reduced.

### Fourth Embodiment

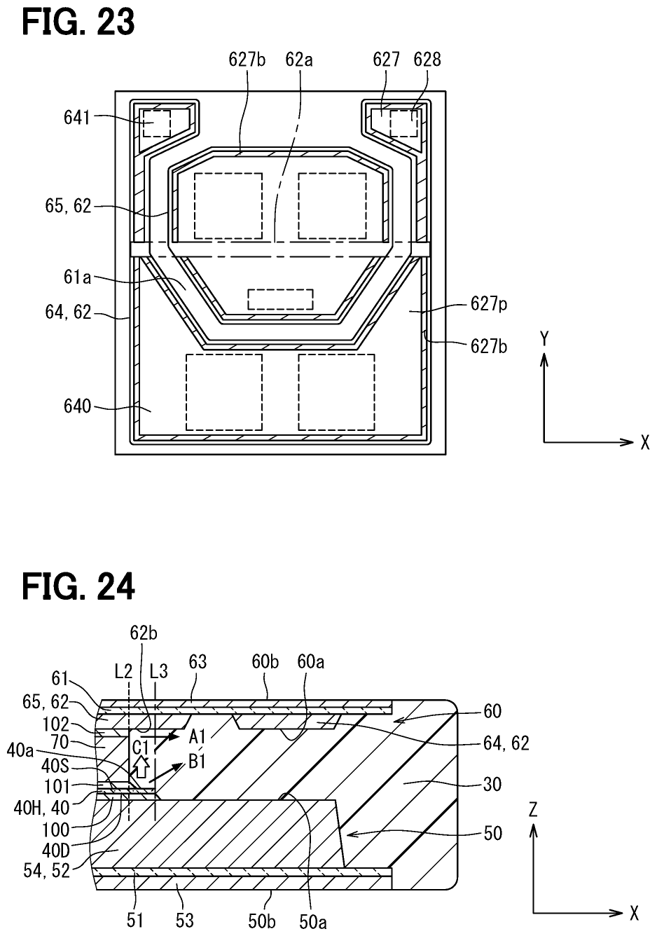

In the first embodiment, the low-adhesion portion 527p is not formed on an entirety of the exposed facing portion 52a, but the metal body annular portion 527b is formed in a portion of the exposed facing portion 52a. That is, priority is given to exhibiting an effect of the metal body annular portion 527b over improving a damage suppression effect of the insulating base material 61 by reducing an area of the high-adhesion portion in the exposed facing portion 52a. On the other hand, in the present embodiment, as shown in FIG. 23, a low-adhesion portion 627p is formed on an entirety of an exposed facing portion 62a in the substrate 60 on the S side. That is, a metal body annular portion 627b is made non-annular by the low-adhesion portion 627p in the exposed facing portion 62a crossing the metal body annular portion 627b.

As described above, in the present embodiment, the low-adhesion portion 627p is formed on an entirety of the exposed facing portion 62a in the substrate 60 on the S side. As a result, an area of the high-adhesion portion in the exposed facing portion 62a can be reduced, and a damage suppression effect for an exposed portion of the insulating base material 51 on the D side can be improved.

### Fifth Embodiment

Also in the present embodiment, similar to the first embodiment, a portion of the front-surface metal bodies 52 and 62 that is not in contact with the insulating base materials 51 and 61 is divided into adhesion portions 527 and 627 and non-adhesion portions 528 and 628. The adhesion portions 527 and 627 are also referred to as a “contact portion” of the front-surface metal bodies 52 and 62 that are in contact with the sealing body 30. The adhesion portions 527 and 627 (contact portions) are divided into high-adhesion portions and low-adhesion portions 527p and 627p.

Here, the surface of the semiconductor element 40 on the D side is connected to the front-surface metal body 52 via the joining material 100. On the other hand, the surface of the semiconductor element 40 on the S side is connected to the front-surface metal body 62 via the joining materials 101 and 102 and the conductive spacer 70. Further, an entirety of the surface of the semiconductor element 40 on the D side is connected to the front-surface metal body 52. On the other hand, a most of the surface of the semiconductor element 40 on the S side is connected to the front-surface metal body 62, but a portion is exposed without being connected to the conductive spacer 70. In this way, the portion of the semiconductor element 40 exposed from the conductive spacer 70 and the joining material 101 is referred to as an element exposed portion 40a (see FIG. 24). The pad 40P described above is provided in the element exposed portion 40a.

Describing in more detail, a protective film made of a resin is formed on the surface of the semiconductor element 40. Examples of materials of the protective film include polyimide (PI). This protective film is also formed in the element exposed portion 40a described above, and hereinafter, a surface of the element exposed portion 40a is referred to as a PI surface.

Of the front-surface metal bodies 52 and 62, a portion facing the semiconductor elements 40 is referred to as an element facing portion 62b. However, for the front-surface metal body 62 on the S side, the conductive spacer 70 is interposed between the front-surface metal body 62 and the semiconductor element 40. Therefore, a region where the front-surface metal body 62 overlaps the conductive spacer 70 in a view from the Z direction cannot be said to face the semiconductor element 40, and is not referred to as the element facing portion. That is, for the front-surface metal body 62 on the S side, a portion facing the element exposed portion 40a is referred to as an element facing portion 62b. More specifically, a portion of the front-surface metal body 62 on the S side that faces a PI surface of the semiconductor element 40, and a portion obtained by projecting the PI surface onto the front-surface metal body 62 in the Z direction, corresponds to the element facing portion 62b.

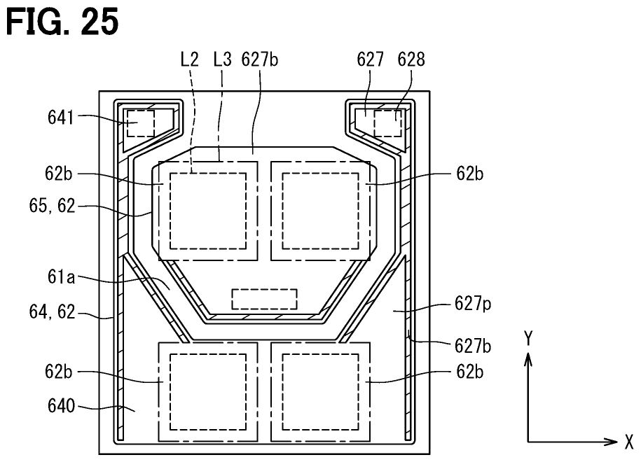

Of the front-surface metal body 62, a portion between a dotted line L2 and an alternate long and short dash line L3 in FIGS. 24 and 25 corresponds to the element facing portion 62b. A portion surrounded by the dotted line L2 in FIG. 25 corresponds to the non-adhesion portion 628 described above. The alternate long and short dash line L3 in FIG. 25 corresponds to an outer profile of the semiconductor element 40. The element facing portion 62b has a shape extending in an annular shape around the semiconductor element 40. The element facing portion 62b is also the adhesion portion 627 because it is in contact with the sealing body 30.

On the other hand, with regard to the front-surface metal body 52 on the D side, there is no intervening object between the front-surface metal body 52 and the semiconductor element 40, and an entirety of a portion of the front-surface metal body 52 surrounded by the alternate long and short dash line L3 corresponds to the element facing portion. However, in the front-surface metal body 52 on the D side, an entirety of the surface of the semiconductor element 40 on the D side is joined to the front-surface metal body 52. Therefore, the adhesion portion 527 (contact portion) that is in close contact with the sealing body 30 does not exist in the element facing portion on the D side.

Here, in the following regions according to the first embodiment, there is a portion where the high-adhesion portion is formed even in the element facing portion 62b. That is, the regions include a region extending in an annular shape along an outer profile of the front-surface metal body 62, a region extending in an annular shape along an outer profile of the semiconductor element 40, and a region between different potentials. On the other hand, in the present embodiment, as shown in FIG. 25, an entirety of the element facing portion 62b is the low-adhesion portion 627p, and formation of the high-adhesion portion on the element facing portion 62b is prohibited even in the above regions.

### <Effects Regarding Element Facing Portion>

If, contrary to the present embodiment, the high-adhesion portion is formed over an entirety of the element facing portion 62b, the following concerns arise. That is, due to a difference in linear expansion coefficient between the sealing body 30 and the front-surface metal body 62, a contact surface of the sealing body 30 that is in contact with the front-surface metal body 62 is pulled by the front-surface metal body 62 in accordance with a temperature change. When the contact surface is the high-adhesion portion, a force with which the sealing body 30 is pulled from the front-surface metal body 62 becomes strong. The pulling force acts in the X direction as indicated by an arrow A1 in FIG. 24.

On the other hand, a contact surface of the sealing body 30 that is in contact with the element exposed portion 40a is pulled in the Z direction in addition to the X direction as indicated by an arrow B1 in FIG. 24, due to occurrence of the pulling force A1. That is, a pulling force in the Z direction acts on the contact surface of the sealing body 30 that is in contact with the element exposed portion 40a, as indicated by an arrow C1. As a result, a stress generated at an interface between the semiconductor element 40 and the sealing body 30 increases, the sealing body 30 peels from the element exposed portion 40a, which leads to a withstand voltage failure of the semiconductor element 40.

In view of this point, in the present embodiment, the low-adhesion portion 627p is formed in at least a portion of the element facing portion 62b. Therefore, compared to a case where an entirety of the element facing portion 62b is formed as the high-adhesion portion, the pulling force A1 generated at the element facing portion 62b can be reduced, and the pulling force C1 acting on the element exposed portion 40a can be reduced. Thus, a concern that the sealing body 30 peels from the element exposed portion 40a can be reduced, and damage to the semiconductor element 40 can be suppressed. Especially in the present embodiment, since formation of the high-adhesion portion on the element facing portion 62b is prohibited and an entirety of the element facing portion 62b is the low-adhesion portion 627p, an effect of reducing the pulling force C1 is large.

Describing in more detail, a portion of the front-surface metal body 62 on the S side that faces the PI surface of the semiconductor element 40 (element facing portion 62b) is the low-adhesion portion 627p in which roughening by a laser or the like is prohibited. Therefore, an interface between the element facing portion 62b and the sealing body 30 has an adhesion force lower than the high-adhesion portion, so that the pulling force A1 can be reduced, and thus a pulling force B1 can be reduced. As a result, a strain generated at an interface between the PI surface and the sealing body 30 can be reduced. Accordingly, since the PI surface and the sealing body 30 are in close contact with each other, occurrence of a withstand voltage failure of the semiconductor element 40 can be prevented.

### <Effects of First Embodiment Compared to Present Embodiment>

Hereinafter, effects of the semiconductor device 20 according to the first embodiment compared to the present embodiment will be described. In the present embodiment, formation of the high-adhesion portion in the element facing portion 62b is prohibited. On the other hand, in the first embodiment described above, a portion of the element facing portion 62b is the high-adhesion portion. However, in the element facing portion 62b, an area where the low-adhesion portion 627p is formed is larger than an area where the high-adhesion portion is formed. Therefore, a reduction of the pulling force A1 generated at the element facing portion 62b can be made sufficiently large, and a damage suppression effect of the semiconductor element 40 can be sufficiently secured.

In the first embodiment, as shown in FIG. 18, in the element facing portion 62b of the front-surface metal body 62, basically, not a high-adhesion portion but the low-adhesion portion 627p is formed. However, exceptionally, in the region between the portions having different potentials, there is a portion where the high-adhesion portion is formed even in the element facing portion 62b. For example, in the linear region of the annular shape along the outer profile of the N wiring 64 or the relay wiring 65, which is also the region between the portions having different potentials and a portion of the element facing portion, not the low-adhesion portion 627p but the high-adhesion portion is formed. That is, even in the region corresponding to the element facing portion 62b, a priority is given to forming the high-adhesion portion in the region between the portions having different potentials. Therefore, the above-described effect of suppressing peeling of the sealing body 30 between different potentials by the high-adhesion portion and suppressing a concern that a leak path is formed between the portions having different potentials is exhibited. Even so, since an entirety of the element facing portion 62b is not formed as the high-adhesion portion, but the low-adhesion portion 627p is formed at least partially, a damage suppression effect of the semiconductor element 40 is also exhibited.

In the first embodiment, as shown in FIG. 18, in the region of the annular shape along the outer profile of the front-surface metal body 62, exceptionally, there is a portion where the high-adhesion portion is formed even in the element facing portion 62b. For example, in the linear region of the annular shape along the outer profile of the N wiring 64 or the relay wiring 65, and which is also a portion of the element facing portion 62b, not the low-adhesion portion 627p but the high-adhesion portion is formed. That is, even in the region corresponding to the element facing portion 62b, a priority is given to forming the metal body annular portion 627b by the high-adhesion portion. Therefore, even if peeling occurs inside surrounded by the metal body annular portion 627b, the above-described effect that a concern that a leak path is formed from the peeling location can be reduced by the metal body annular portion 627b is exhibited. Even so, since the low-adhesion portion 627p is formed on at least a portion of the element facing portion 62b, a damage suppression effect of the semiconductor element 40 is also exhibited.

### (Other Embodiments)

In the above embodiments, the laser roughening is employed when forming the high-adhesion portion by the roughening process that form the surface roughness of the front-surface metal bodies 52 and 62. On the other hand, the high-adhesion portion may be formed by roughening using a roughening plating, sandblasting, a chemical treatment, or the like. Instead of forming the high-adhesion portion by the roughening process, the high-adhesion portion may be formed using an adhesive or a pressure-sensitive adhesive.

In the above embodiments, the high-adhesion portion is arranged over an entirety between the portions having different potentials on the substrates 50 and 60. On the other hand, the high-adhesion portion may be arranged in a portion between the portions having different potentials. For example, in the example shown in FIG. 17, a boundary (exposed portion) between the P wiring 54 and the relay wiring 55 has a shape linearly extending in the X direction. Further, the metal body annular portion 527b is arranged over an entirety of the boundary. On the other hand, the metal body annular portion 527b may be changed to a non-annular shape, and the metal body annular portion 527b may be arranged at a portion of the boundary.

In the above embodiments, at least a portion of the high-adhesion portion has the shape extending in the annular shape, and at least a portion of the low-adhesion portions 527p and 627p is arranged so as to be surrounded by the high-adhesion portion. On the other hand, the annular portion of the high-adhesion portion may be eliminated.

In the above embodiments, in the single substrate 50, 60, the area of the high-adhesion portion is smaller than the area of the low-adhesion portion 527p, 627p, and a majority is the low-adhesion portion 527p, 627p. On the other hand, an area of the high-adhesion portion may be larger than the area of the low-adhesion portion 527p, 627p, so that a majority may be the high-adhesion portion.

In the above embodiments, in the exposed facing portion 52a, the area where the low-adhesion portion 527p is formed is larger than the area where the high-adhesion portion is formed, and a majority of the exposed facing portion 52a is the low-adhesion portion 527p. On the other hand, the relationship of areas described above may be reversed, and a majority of the exposed facing portion 52a may be the high-adhesion portion.

In the above embodiments, targets for forming both the high-adhesion portion and the low-adhesion portion are the substrate 50 on the D side and the substrate 60 on the S side. On the other hand, the target may be either the substrate 50 on the D side or the substrate 60 on the S side. In that case, the other substrate may have no high-adhesion portion and only a low-adhesion portion, or may have no low-adhesion portion and only a high-adhesion portion.

In the above embodiments, in the substrate 50 on the D side, the line widths of the element annular portion 527a, the metal body annular portion 527b, and the terminal annular portion 527c are set to dimensions smaller than a separation distance between the P wiring 54 and the relay wiring 55. On the other hand, the line widths may be larger than the separation distance. Similarly, in the substrate 60 on the S side, the line width of the metal body annular portion 627b may be thinner or thicker than a separation distance between the N wiring 64 and the relay wiring 65.

In the above embodiments, an example of a double-sided heat dissipation structure semiconductor device 20 having the pair of substrates 50 and 60 has been described, but the present disclosure is not limited thereto. Application to a single-sided heat dissipation structure semiconductor device 20 including one of the substrates, such as only the substrate 50 to which the drain electrode 40D (first main electrode) is connected is also possible. The rear-surface metal bodies 53 and 63 may be eliminated, an electrically insulating heat dissipation gel may be applied to rear surfaces of the insulating base materials 51 and 61, and a heat sink may be thermally connected to the heat dissipation gel.

In the above embodiments, an example in which the semiconductor device 20 includes the semiconductor elements 40H and 40L has been described, but the present disclosure is not limited thereto. A semiconductor element 40 configuring only one of the arms may be provided. The semiconductor device 20 may include only one semiconductor element 40, for example.

In the above embodiments, the element facing portion 62b has the shape extending in the annular shape along the outer profile of the semiconductor element 40. On the other hand, the element facing portion 62b is not limited to the annular shape, and may have, for example, a shape extending linearly along one side of the semiconductor element 40.

In the above embodiments, also in the substrate 60 on the S side, the high-adhesion portion may be formed in the annular shape along the outer profile of the semiconductor elements 40H and 40L, similar to the substrate 50 on the D side. However, even in a region extending along the outer profile of the semiconductor elements 40H and 40L, the low-adhesion portion 627p may be formed in an exposed facing portion 62a or an element facing portion 62b. Alternatively, even in the exposed facing portion 62a or the element facing portion 62b, a priority may be given to forming the high-adhesion portion in the annular shape along the outer profile of the semiconductor elements 40H and 40L.

Configurations described in the present embodiment can be combined with any of configurations described in the first embodiment, the second embodiment, the third embodiment, the fourth embodiment, the fifth embodiment, and other embodiments. Furthermore, although the present disclosure is described in accordance with embodiments, it is understood that the present disclosure is not limited to the embodiments or structures. The present disclosure also covers various modified examples and modifications within an equivalent range. In addition, although various combinations and forms are shown in the present disclosure, other combinations and forms including only one element, more elements, or less elements are also within the scope and technical idea of the present disclosure.

### Disclosure of Technical Concepts

This specification discloses a plurality of technical concepts described in a plurality of clauses listed below. Some clauses may be described in a multiple dependent form that alternatively quotes preceding clauses in subsequent clauses. Further, some clauses may be described in a multiple dependent form referring to another multiple dependent form that quotes other multiple dependent forms. Clauses described in these multiple dependent forms define a plurality of technical concepts.

### Technical Concept 1

A semiconductor device includes: a semiconductor element (40) having a main electrode (40D, 40S); a substrate (50, 60) including an insulating base material (51, 61), and a front-surface metal body (52, 62) disposed on a surface of the insulating base material and electrically connected to the main electrode; and a sealing body (30) sealing at least a portion of the substrate including the front-surface metal body, and the semiconductor element. A contact portion of the front-surface metal body being in contact with the sealing body includes a high-adhesion portion (527a, 527b, 527c, 527d, 627b) having higher adhesion to the sealing body, and a low-adhesion portion (527p, 627p) having lower adhesion to the sealing body than the high-adhesion portion. At least a portion of the high-adhesion portion is disposed between portions of the substrate having different potentials.

### Technical Concept 2

In the semiconductor device according to Technical Concept 1, the high-adhesion portion includes a metal body annular portion (527b, 627b) extending in an annular shape along an outer profile of the front-surface metal body.

### Technical Concept 3

In the semiconductor device according to Technical Concept 1 or 2, the high-adhesion portion includes an element annular portion (527a) extending in an annular shape along an outer profile of the semiconductor element.

### Technical Concept 4

In the semiconductor device according to any one of Technical Concepts 1 to 3, an external connection terminal (90) for electrically connecting to an external device is connected to the front-surface metal body, and the high-adhesion portion includes a terminal annular portion (527c) extending in an annular shape so as to surround a connection portion between the front-surface metal body and the external connection terminal.

### Technical Concept 5

In the semiconductor device according to any one of Technical Concepts 1 to 4, the main electrode includes a first main electrode (40D) provided on a front surface of the semiconductor element, and a second main electrode (40S) provided on a rear surface of the semiconductor element. The substrate includes a first substrate (50) connected to the first main electrode, and a second substrate (60) connected to the second main electrode. The high-adhesion portion and the low-adhesion portion are formed in both the first substrate and the second substrate.

### Technical Concept 6

In the semiconductor device according to any one of Technical Concepts 1 to 5, at least a portion of the high-adhesion portion has a shape extending in an annular shape, and at least a portion of the low-adhesion portion is surrounded by the high-adhesion portion.

### Technical Concept 7

In the semiconductor device according to any one of Technical Concepts 1 to 6, an area of the high-adhesion portion in a single substrate is smaller than an area of the low-adhesion portion.

### Technical Concept 8

In the semiconductor device according to any one of Technical Concepts 1 to 7, the main electrode includes a first main electrode (40D) provided on a front surface of the semiconductor element, and a second main electrode (40S) provided on a rear surface of the semiconductor element. The substrate includes a first substrate (50) connected to the first main electrode, and a second substrate (60) connected to the second main electrode. In one of the first substrate or the second substrate, a portion where the insulating base material is exposed without the front-surface metal body being provided is referred to as an exposed portion. Further, a portion of the front-surface metal body of the other of the first substrate and the second substrate facing the exposed portion is referred to as an exposed facing portion. In this case, at least a portion of the low-adhesion portion is formed in the exposed facing portion.

### Technical Concept 9

In the semiconductor device according to Technical Concept 8, in the exposed facing portion, an area where the low-adhesion portion is formed is larger than an area where the high-adhesion portion is formed.

### Technical Concept 10

In the semiconductor device according to Technical Concept 8 or 9, in the other of the first substrate and the second substrate, in a region between the portions having different potentials, there is a portion where the high-adhesion portion is formed even in the exposed facing portion.

### Technical Concept 11

In the semiconductor device according to any one of Technical Concepts 8 to 10, in a region extending in an annular shape along an outer profile of the front-surface metal body of the substrate, there is a portion where the high-adhesion portion is formed even in the exposed facing portion.

### Technical Concept 12

In the semiconductor device according to any one of Technical Concepts 8 to 11, in a region extending in an annular shape along an outer profile of the semiconductor element of the substrate, there is a portion where the high-adhesion portion is formed even in the exposed facing portion.

### Technical Concept 13

A semiconductor device includes: a semiconductor element (40) having main electrodes (40D, 40S) on both surfaces; a substrate (50, 60) including an insulating base material (51, 61), and a front-surface metal body (52, 62) disposed on a surface of the insulating base material and electrically connected to at least one of the main electrodes; and a sealing body (30) sealing at least a portion of the substrate including the front-surface metal body, and the semiconductor element. A contact portion of the front-surface metal body being in contact with the sealing body includes a high-adhesion portion (527a, 527b, 527c, 527d, 627b) having higher adhesion to the sealing body, and a low-adhesion portion (527p, 627p) having lower adhesion to the sealing body than the high-adhesion portion. A portion of the contact portion facing the semiconductor element is referred to as an element facing portion (62b), and at least a portion of the low-adhesion portion is formed in the element facing portion.

### Technical Concept 14

In the semiconductor device according to Technical Concept 13, in the element facing portion, an area where the low-adhesion portion is formed is larger than an area where the high-adhesion portion is formed.

### Technical Concept 15

In the semiconductor device according to Technical Concept 13 or 14, in a region between the portions of the substrate having different potentials, there is a portion where the high-adhesion portion is formed even in the element facing portion.

### Technical Concept 16

In the semiconductor device according to any one of Technical Concepts 13 to 15, in a region extending in an annular shape along an outer profile of the front-surface metal body of the substrate, there is a portion where the high-adhesion portion is formed even in the element facing portion.

What is claimed is:

1. A semiconductor device comprising:
a semiconductor element having a main electrode;
a substrate including an insulating base material, and a front-surface metal body disposed on a front surface of the insulating base material and electrically connected to the main electrode; and
a sealing body sealing at least a portion of the substrate including the front-surface metal body, and the semiconductor element, wherein the front-surface metal body has a contact portion in contact with the sealing body,
the contact portion includes a high-adhesion portion having higher adhesion to the sealing body and a low-adhesion portion having lower adhesion to the sealing body than the high-adhesion portion, and
at least a portion of the high-adhesion portion is disposed between portions of the substrate having different potentials.

2. The semiconductor device according to claim 1, wherein
the high-adhesion portion includes a metal body annular portion extending in an annular shape along an outer profile of the front-surface metal body.

3. The semiconductor device according to claim 1, wherein
the high-adhesion portion includes an element annular portion extending in an annular shape along an outer profile of the semiconductor element.

4. The semiconductor device according to claim 1, further comprising:
an external connection terminal connected to the front-surface metal body for electrically connecting to an external device, and
the high-adhesion portion includes a terminal annular portion extending in an annular shape so as to surround a connection portion between the front-surface metal body and the external connection terminal.

5. The semiconductor device according to claim 1, wherein
the main electrode includes a first main electrode disposed on a front surface of the semiconductor element, and a second main electrode disposed on a rear surface of the semiconductor element,
the substrate includes a first substrate connected to the first main electrode, and a second substrate connected to the second main electrode, and
both the first substrate and the second substrate have the high-adhesion portion and the low-adhesion portion.

6. The semiconductor device according to claim 1, wherein
at least a portion of the high-adhesion portion has a shape extending in an annular shape, and
at least a portion of the low-adhesion portion is surrounded by the high-adhesion portion.

7. The semiconductor device according to claim 1, wherein
an area of the high-adhesion portion is smaller than an area of the low-adhesion portion, in the substrate which is a single substrate.
